(19) United States
(12) Patent Application Publication
(10) Pub. No.: US 2026/0221207 A1
(43) Pub. Date: Jul. 30, 2026

(54) MEMORY DEVICES, METHODS THEREOF, AND MEMORY SYSTEMS

(71) Applicant: Yangtze Memory Technologies Co., Ltd., Wuhan (CN)

(72) Inventors: Ying Huang, Wuhan (CN); HongTao Liu, Wuhan (CN); Tingze Wang, Wuhan (CN); Pengyu Xu, Wuhan (CN); Yuxin Liu, Wuhan (CN); Lei Jin, Wuhan (CN)

(21) Appl. No.: 19/236,276

(22) Filed: Jun. 12, 2025

(30) Foreign Application Priority Data
Jan. 27, 2025 (CN) 202510127511.8

(51) Int. Cl. G11C 16/34; G11C 16/08; G11C 16/14

(52) U.S. Cl. CPC G11C 16/3495; G11C 16/08; G11C 16/14

(57) ABSTRACT

Examples of the present disclosure provide a memory device, an operation method thereof, and a memory system. The memory device includes a memory array and a peripheral circuit coupled to the memory array and configured to: apply a first erase voltage to a source line and a first pass voltage to a first word line coupled to a first memory cell during performing a first odd-even erase operation; and apply a second erase voltage to the source line and a second pass voltage to the first word line during performing a second odd-even erase operation. A first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

### CROSS-REFERENCE TO RELATED APPLICATION

This application claims priority to and the benefit of Chinese Patent Application 202510127511.8, filed on January 27, 2025, which is hereby incorporated by reference in its entirety.

### TECHNICAL FIELD

Examples of the present disclosure relate to the field of semiconductor technology, and in particular, to memory devices, methods thereof, and memory systems.

### BACKGROUND

Memory is a storage device used to store information in modern information technology. As a typical non-volatile semiconductor memory, NAND (Not-And) flash memory has become a mainstream product in the storage market due to its high storage density, controllable production cost, considerable program/erase speed and retention characteristics.

### BRIEF DESCRIPTION OF THE DRAWINGS

FIG. 1 is a schematic diagram of an example system with a memory system according to an example of the present disclosure.

FIG. 2A is a schematic diagram of an example memory card with a memory system according to an example of the present disclosure.

FIG. 2B is a schematic diagram of an example solid state drive with a memory system according to an example of the present disclosure.

FIG. 3A is a schematic diagram of arrangement of memory cells of a three-dimensional NAND memory according to an example of the present disclosure.

FIG. 3B is a schematic diagram of an example memory comprising a peripheral circuit according to an example of the present disclosure.

FIG. 4 is a schematic cross-sectional view of a memory array comprising NAND memory strings according to an example of the present disclosure.

FIG. 5 is a schematic diagram of an example memory comprising a memory cell array and a peripheral circuit according to an example of the present disclosure.

FIGS. 6A and 6B are schematic diagrams of charge distribution of a memory cell before and after an erase cycle according to an example of the present disclosure.

FIG. 7A is a schematic diagram of a relationship between the number of program/erase cycles and charge loss of a memory cell according to an example of the present disclosure.

FIG. 7B is a schematic diagram of an example in which the number of program/erase cycles is not associated with a pass voltage Vₚₐₛₛ and an erase voltage Vₑᵣₐₛₑ according to an example of the present disclosure.

FIG. 8 is a schematic waveform diagram of an odd-even erase operation according to an example of the present disclosure.

FIG. 9 is a schematic waveform diagram of comparison between a first odd-even erase operation and a second odd-even erase operation according to an example of the present disclosure.

FIG. 10A is a schematic diagram of an example of step-wise reducing the pass voltage Vₚₐₛₛ and the erase voltage Vₑᵣₐₛₑ according to the number of program/erase cycles according to an example of the present disclosure.

FIG. 10B is a schematic diagram of an example of step-wise reducing the pass voltage Vₚₐₛₛ according to the number of program/erase cycles according to an example of the present disclosure.

FIG. 10C is a schematic diagram of an example of step-wise reducing the erase voltage Vₑᵣₐₛₑ according to the number of program/erase cycles according to an example of the present disclosure.

FIG. 11A is a schematic diagram of an example of sequentially reducing a pass voltage Vₚₐₛₛ and sequentially reducing an erase voltage Vₑᵣₐₛₑ according to the number of program/erase cycles according to an example of the present disclosure.

FIG. 11B is a schematic diagram of an example of sequentially reducing a pass voltage Vₚₐₛₛ according to the number of program/erase cycles according to an example of the present disclosure.

FIG. 11C is a schematic diagram of an example of sequentially reducing an erase voltage Vₑᵣₐₛₑ according to the number of program/erase cycles according to an example of the present disclosure.

FIG. 12 is a schematic flow diagram of an operation method of a memory device according to an example of the present disclosure.

### DETAILED DESCRIPTION

The technical solutions in the examples of the present disclosure will be clearly and completely described below with reference to implementations and accompanying drawings of the present disclosure. Apparently, the described examples are merely some rather than all of the examples of the present disclosure. All other implementations obtained based on the examples of the present disclosure by those of ordinary skill in the art without creative efforts shall fall within the protection scope of the present disclosure.

In the following description, numerous specific details are set forth in order to provide a more thorough understanding of the present disclosure. However, it will be apparent to those skilled in the art that the present disclosure may be implemented without one or more of these details. In other examples, in order to avoid confusion with the present disclosure, some technical features known in the art are not described; that is, not all features of actual examples are described herein, and well-known functions and structures are not described in detail.

In the drawings, the sizes of layers, regions, elements and their relative sizes may be exaggerated for clarity. Like numbers refer to like elements throughout the description.

It will be understood that when an element or layer is referred to as being “on”, “adjacent to”, “connected to” or “coupled to” another element or layer, it can be directly on, adjacent to, connected or coupled to the other element or layer, or intervening elements or layers may be present. In contrast, when an element is referred to as being “directly on,” “directly adjacent to,” “directly connected to,” or “directly coupled to” another element or layer, there are no intervening elements or layers present. It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below may denote a second element, component, region, layer or section without departing from the teachings of the present disclosure. When the second element, component, region, layer or part is discussed, it does not indicate that the first element, component, region, layer or part is necessarily present in the present disclosure.

Spatially relative terms, such as “under”, “below”, “lower”, “beneath”, “above”, “upper”, “bottom”, “top” and the like, may be used herein for ease of description to describe one element’s or feature's relationship to another element or feature as illustrated in the figures. It will be understood that the spatially relative terms may encompass different orientations of the device in use or operation in addition to the orientation depicted in the figures. For example, if the device in the figures is turned over, elements described as "under", “below” or “beneath” other elements or features would then be oriented “above” the other elements or features. Thus, the example terms “below” and “under” can encompass both an orientation of above and below. The device may be otherwise oriented (rotated 90 degrees or at other orientations) and the spatially relative descriptors used herein may be interpreted accordingly.

The terminology used herein is for the purpose of describing particular examples only and is not intended to be a limitation of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of the associated listed items.

In order to thoroughly understand this disclosure, detailed steps and detailed structures are provided in the following description, to explain the technical solutions of the present disclosure. Certain examples of the present disclosure are described in detail below, but the present disclosure may also have other implementations in addition to those detailed descriptions.

With the increasingly high requirements on memory, examples disclosed herein optimize an algorithm of an erase operation to improve the reliability of data retention of memory while avoiding serious degradation of the memory cells caused by the erase operation, so as to improve the reliability of the memory.

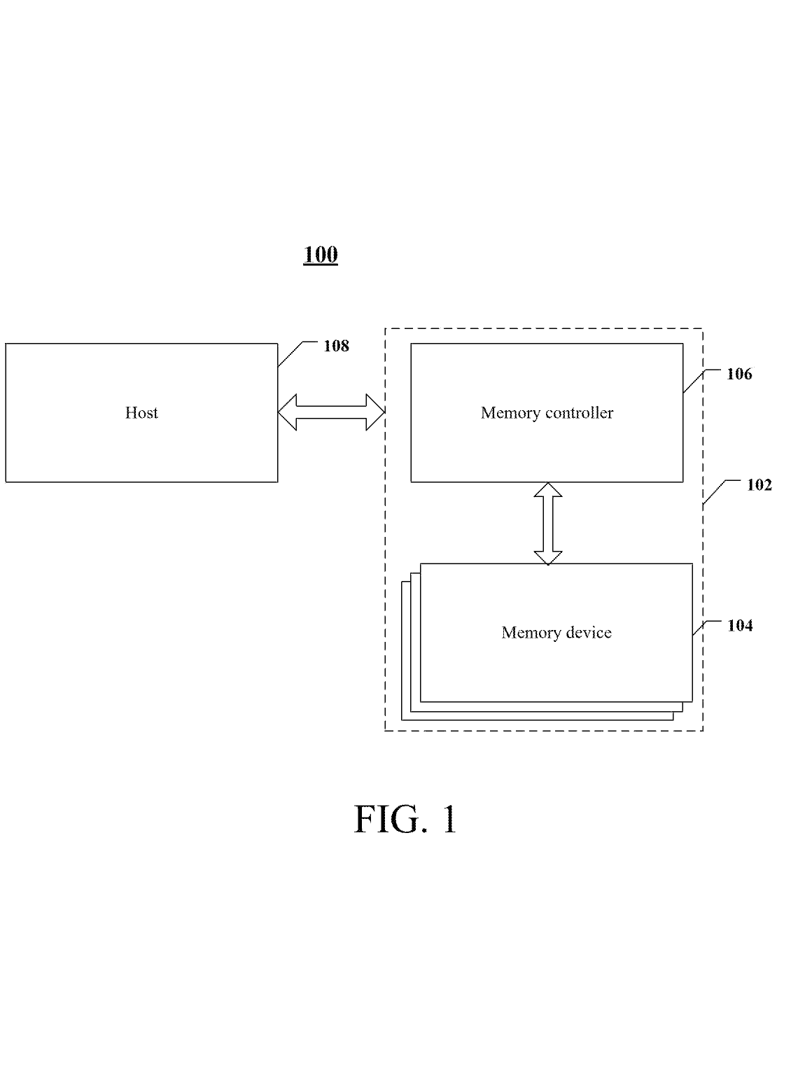

FIG. 1 illustrates a block diagram of an example system 100 with a memory in accordance with some aspects of the present disclosure. The system 100 may be a mobile phone, desktop computer, laptop computer, tablet computer, vehicle computer, gaming console, printer, positioning device, wearable electronic device, smart sensor, virtual reality (VR) device, augmented reality (AR) device, or any other suitable electronic device with a memory therein. As shown in FIG. 1, system 100 may include a host 108 and a memory system 102 having one or more memory devices 104 and a memory controller 106. The host 108 may be a processor (e.g., a central processing unit (CPU)) or a system on chip (SoC) (e.g., an application processor (AP)) of an electronic device. The host 108 can be configured to send data to the memory device 104 or receive data from the memory device 104.

The memory device 104 may be any memory disclosed in the present disclosure. As disclosed in detail below, the memory device 104 (e.g., a NAND flash memory (e.g., a three-dimensional (3D) NAND flash memory)) may have a reduced leakage current from a drive transistor (e.g., a string driver) coupled to an unselected word line during an erase operation, which allows for further scaling down of the drive transistor.

According to some implementations, the memory controller 106 is coupled to the memory device 104 and the host 108, and is configured to control the memory device 104. Memory controller 106 can manage data stored in memory device 104 and communicate with host 108. In some implementations, the memory controller 106 is designed for operation in low duty cycle environments, such as secure digital (SD) cards, compact flash (CF) cards, universal serial bus (USB) flash drives, or other media for use in electronic devices such as personal calculators, digital cameras, mobile phones, and the like. In some implementations, the memory controller 106 is designed for operation in a high duty cycle environment such as a solid-state drive (SSD) or embedded Multi Media Card (eMMC) that serves as data storage for mobile devices such as smartphones, tablet computers, laptop computers, and the like, as well as enterprise storage arrays.

Memory controller 106 may be configured to control operations of a memory device 104, such as read, erase, and program operations. The memory controller 106 can also be configured to manage various functions with respect to data stored or to be stored in the memory device 104 including, but not limited to, bad block management, garbage collection, logical-to-physical address translation, wear leveling, etc. In some implementations, the memory controller 106 is also configured to process error correction codes (ECCs) for data read from or written to the memory devices 104. Memory controller 106 may also perform any other suitable functions, such as formatting memory device 104. Memory controller 106 may communicate with an external device (e.g., host 108) according to a particular communication protocol. For example, the memory controller 106 may communicate with the external device through at least one of various interface protocols, such as a USB protocol, an MMC protocol, a Peripheral Component Interconnect (PCI) protocol, PCI Express (PCI-E) protocol, an Advanced Technology Attachment (ATA) protocol, a Serial ATA protocol, a Parallel ATA protocol, a Small Computer Small Interface (SCSI) protocol, an Enhanced Small Disk Interface (ESDI) protocol, an Integrated Drive Electronics (IDE) protocol, a Firewire protocol, etc.

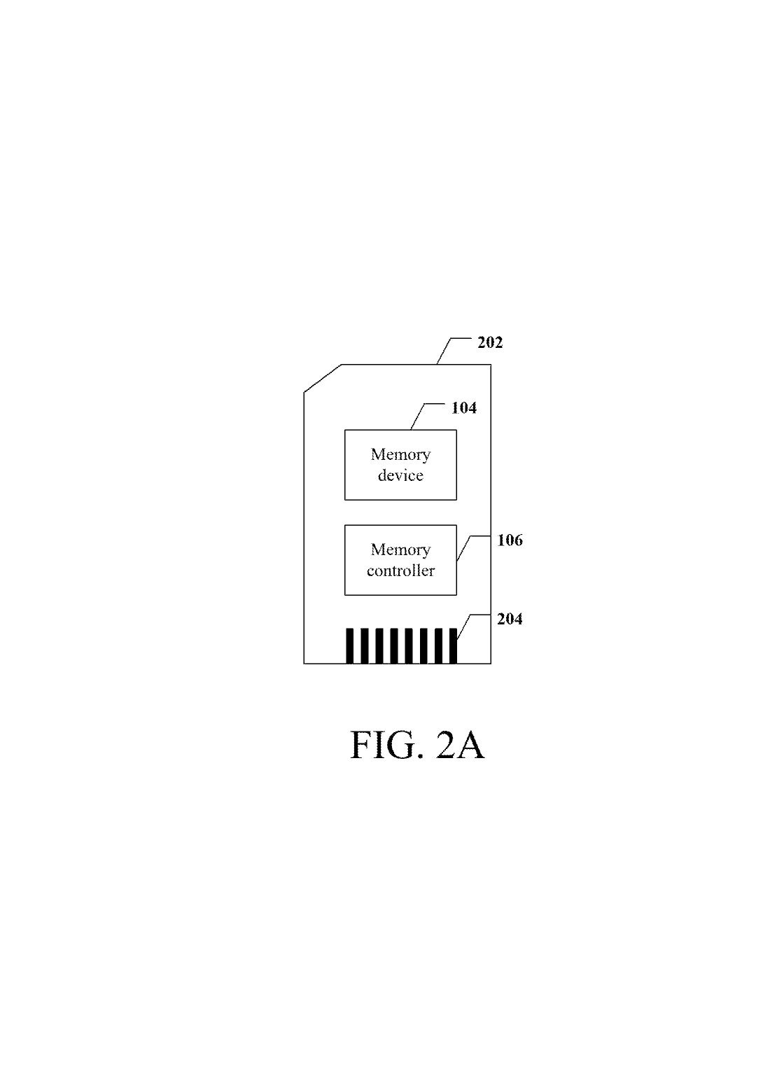

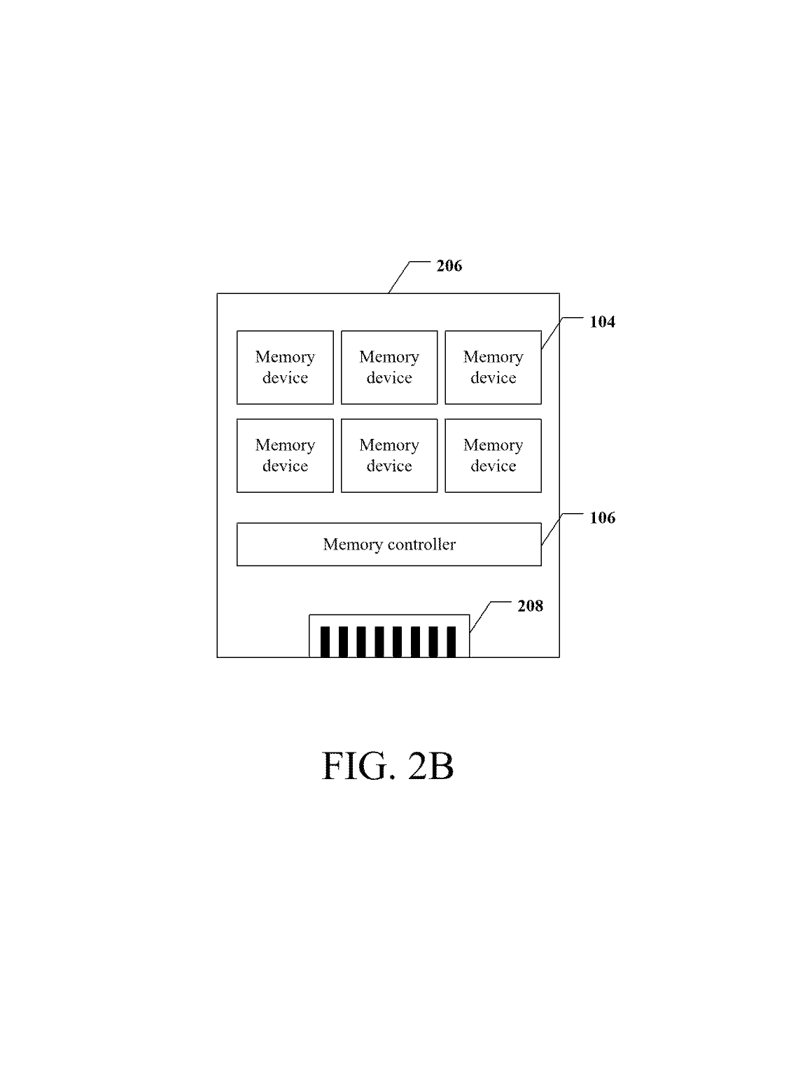

The memory controller 106 and one or more memory devices 104 may be integrated into various types of storage devices, for example, included in the same package (e.g., a Universal Flash Storage (UFS) package or an eMMC package). That is, the memory system 102 may be implemented and packaged into different types of end electronic products. In one example as shown in FIG. 2A, the memory controller 106 and a single memory device 104 may be integrated into memory card 202. The memory card 202 may include a PC card (PCMCIA, Personal Computer Memory Card International Association), CF card, smart media (SM) card, memory stick, multimedia card (MMC, reduced-size MMC (RS-MMC), MMCmicro), SD card (SD, miniSD, microSD, secure digital high capacity (SDHC)), UFS, etc. Memory card 202 may also include a memory card connector 204 that couples memory card 202 with a host (e.g., host 108 in FIG. 1). In another example as shown in FIG. 2B, memory controller 106 and plurality of memory devices 104 may be integrated into SSD 206. SSD 206 may also include an SSD connector 208 that couples the SSD 206 with a host (e.g., host 108 in FIG. 1). In some implementations, the storage capacity and/or operating speed of the SSD 206 is greater than that of the memory card 202.

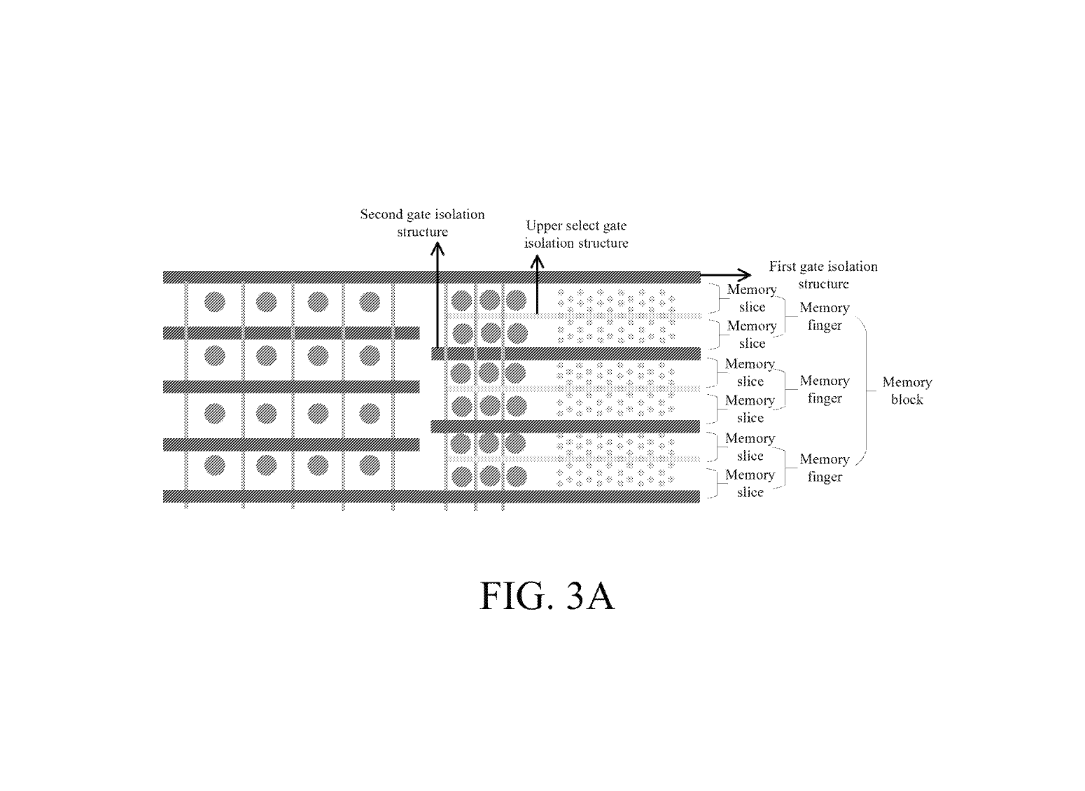

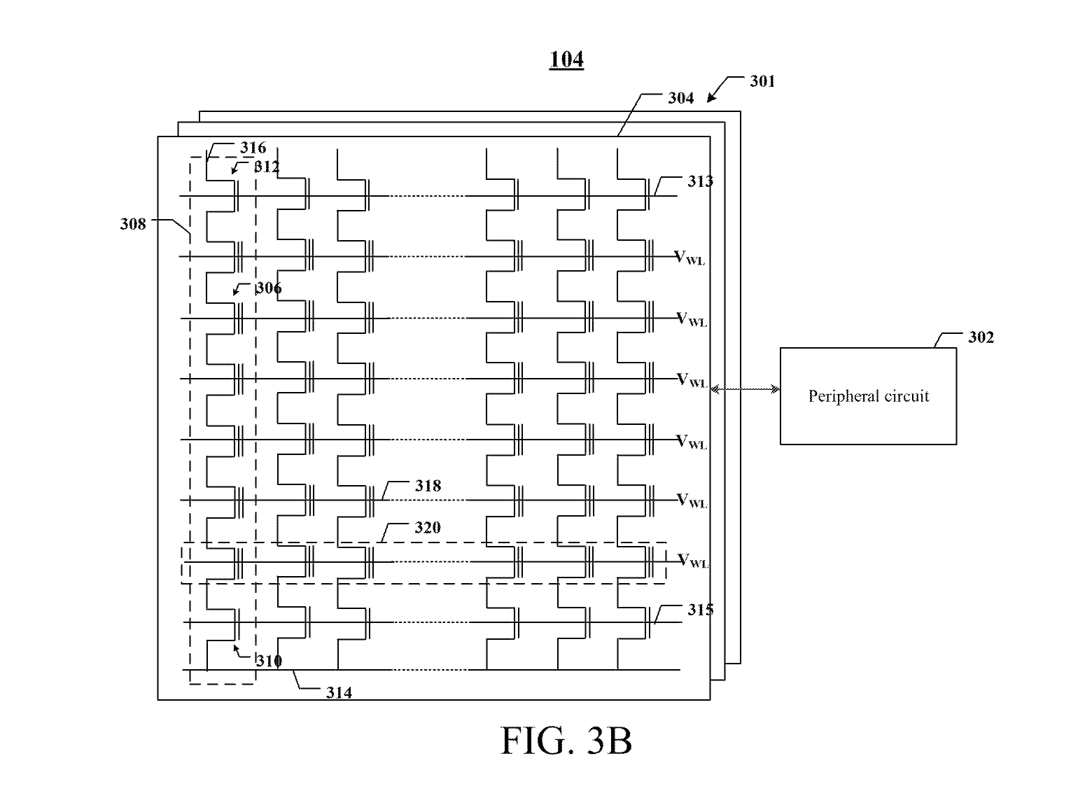

FIG. 3A shows a schematic structural diagram of a memory array of a three-dimensional NAND memory as an example. As shown in FIG. 3A, the memory array of the three-dimensional NAND memory is composed of a plurality of parallel staggered memory cell rows parallel to a gate isolation structure, each two memory cell rows are separated by a gate isolation structure and an upper select gate isolation structure (e.g., a top select gate isolation structure), and each memory cell row includes a plurality of memory cells. The gate isolation structure may include a first gate isolation structure and a second gate isolation structure, the first gate isolation structure divides the memory array into a plurality of memory blocks, the plurality of second gate isolation structures may divide the memory blocks into a plurality of memory fingers, and the upper select gate isolation structure disposed in the middle of each memory finger may divide the memory finger into two parts, thereby dividing the memory finger into two memory slices.

It should be noted that the number of memory cell rows between the gate isolation structure and the upper select gate isolation structure shown in FIG. 3A is only an example, and is not intended to limit the number of memory cell rows included in the memory region of the three-dimensional NAND memory in the present disclosure. In practical applications, the number of memory cell rows included in one memory finger may be adjusted according to actual conditions, such as 2, 4, 8, 16, etc.

FIG. 3B shows a schematic circuit diagram of an example memory 300 including a memory array and peripheral circuit according to some aspects of the present disclosure. Memory 300 may be an example of memory device 104 in FIG. 1. The memory 300 may include a memory array 301 and peripheral circuit 302 coupled to the memory array 301. Taking the memory array 301 as a three-dimensional NAND memory array as an example, the memory cells 306 are provided in the form of an array of NAND memory strings 308, and each NAND memory string 308 extends vertically above a substrate (not shown). In some implementations, each NAND memory string 308 includes a plurality of memory cells 306 coupled in series and vertically stacked. Each memory cell 306 can hold a continuous analog value, e.g., voltage or charge, depending on the number of electrons trapped within the region of the memory cell 306. Each memory cell 306 may be a floating gate type memory cell including a floating gate transistor, or a charge trapping type memory cell including a charge trapping transistor.

In some implementations, each memory cell 306 is a single-level cell (SLC) that has two possible memory states and thus can store one bit of data, that is, one memory cell stores one bit of data, and thus each memory cell has two states, specifically 0 and 1. For example, a first memory state “0” may correspond to a first voltage range and a second memory state “1” may correspond to a second voltage range. In some implementations, each memory cell 306 is a multi-level cell capable of storing more than a single bit of data in more than four memory states. For example, a multi-level cell (MLC) stores two bits of data per cell, stores three bits per cell (also referred to as a triple-level cell (TLC)), or stores four bits per cell (also referred to as a quad-level cell (QLC)). Taking an SLC memory cell as an example, the SLC memory cell has one erase state and one program state, the erase state is denoted as L0, and the program state is denoted as L1.

As shown in FIG. 3B, each NAND memory string 308 may include a bottom select gate (BSG) 310 at its source end and an top select gate (TSG) 312 at its drain end. The BSG 310 and the TSG 312 can be configured to activate the selected NAND memory string 308 during read and program operations. In some implementations, the sources of NAND memory strings 308 in the same memory block 304 are coupled by the same source line (SL) 314 (e.g., a common SL). In other words, according to some examples, all NAND memory strings 308 in the same memory block 304 have an array common source (ACS). According to some examples, the TSG 312 of each NAND memory string 308 is coupled to a corresponding bit line (BL) 316 from which data may be read or written via an output bus (not shown). In some implementations, each NAND memory string 308 is configured to be selected or deselected by applying a select voltage (e.g., above a threshold voltage of a transistor having a TSG 312) or a deselect voltage (e.g., 0V) to a corresponding TSG 312 via one or more of the TSG lines 313, and/or by applying a select voltage (e.g., above a threshold voltage of a transistor having a BSG 310) or a deselect voltage (e.g., 0V) to a corresponding BSG 310 via one or more of the BSG lines 315.

As shown in FIG. 3B, the NAND memory strings 308 may be organized into a plurality of memory blocks 304, each of memory blocks 304 may have a common source line 314 (e.g., coupled to ground). In some examples, each memory block 304 is a basic unit of data for an erase operation, e.g., all memory cells 306 on the same memory block 304 are erased at the same time. To erase the memory cells 306 in the selected memory block 304, the source lines 314 coupled to the selected memory block 304 and the unselected memory blocks in the same plane as the selected memory block 304 may be biased with an erase voltage (Vₑᵣₛ), e.g., a high positive voltage (e.g., 20V or higher). It will be appreciated that in some examples, an erase operation may be performed at a half memory block level, at a quarter memory block level, or at a level having any suitable number of memory blocks or any suitable fraction of memory blocks. The memory cells 306 of the adjacent NAND memory string 308 may be coupled through a word line 318, and the selected word line 318 may be biased with a read and program voltage V_{WL} (e.g., a read voltage (e.g., 0.3V), a program voltage (e.g., 3V)), thereby selecting which row of the memory cells 306 to be affected by the read and program operation. In some implementations, each word line 318 is coupled to a page 320 of memory cells 306, and page 320 is the basic unit of data for a program operation. The size of the page 320 in bits may be related to the number of NAND memory strings 308 coupled by a word line 318 in one memory block 304. Each word line 318 can include a plurality of control gates (gate electrodes) at each memory cell 306 in a corresponding page 320 and a gate line coupling the control gates. With reference to FIG. 3A, a page 320 includes a plurality of memory cells 306, the plurality of memory cells are separated by an upper select gate isolation structure and a gate isolation structure, the plurality of memory cells between the upper select gate isolation structure and the gate isolation structure are arranged into a plurality of memory cell rows, and each memory cell row is parallel to the gate isolation structure and the upper select gate isolation structure. The memory cells in the memory slices sharing the same word line form a programmable (read/write) page.

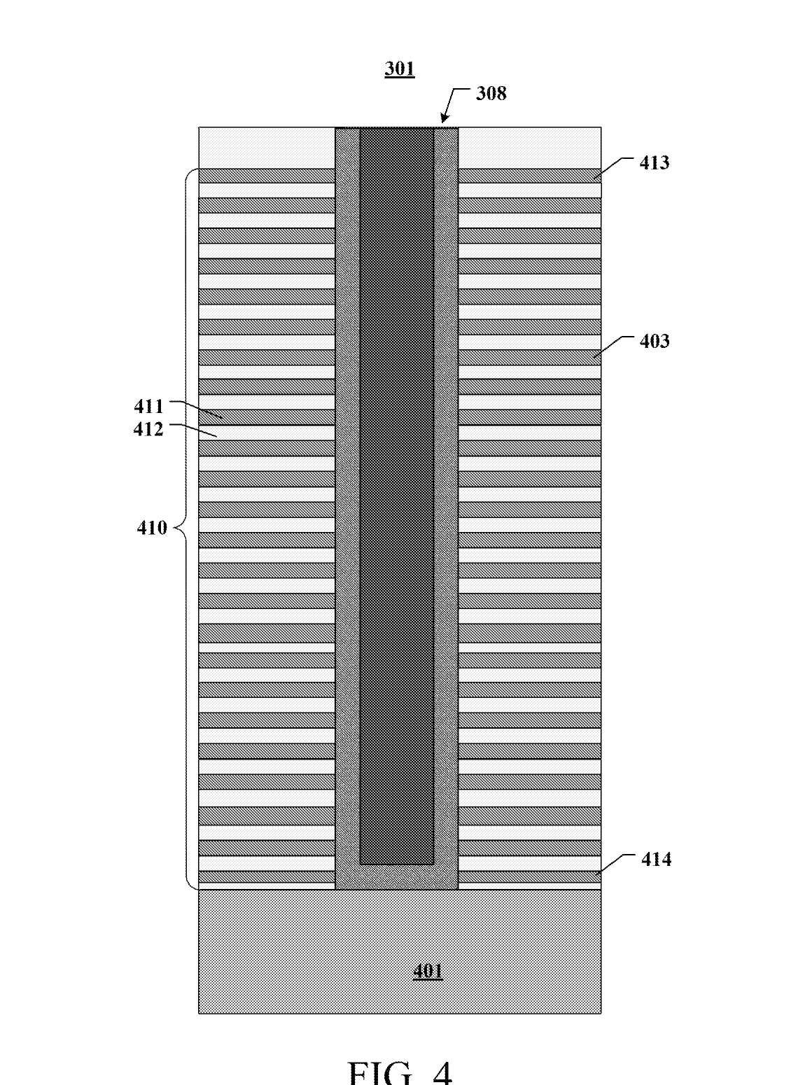

FIG. 4 shows a schematic cross-sectional view of an example memory array 301 including NAND memory strings 308 according to some aspects of the present disclosure. As shown in FIG. 4, the NAND memory string 308 may include a stack structure 410, and the stack structure 410 includes a plurality of gate layers 411 and a plurality of insulating layers 412 stacked alternately in sequence, and a memory string 308 vertically extending through the gate layers 411 and the insulating layers 412. The gate layers 411 and the insulating layers 412 may be stacked alternately, and two adjacent gate layers 411 are separated by one insulating layer 412. The number of pairs of gate layers 411 and insulating layers 412 in the stack structure 410 may determine the number of memory cells included in the memory array 301.

A composition material of the gate layer 411 may include a conductive material. The conductive material includes, but is not limited to, tungsten (W), cobalt (Co), copper (Cu), aluminum (Al), polysilicon, doped silicon, silicide, or any combination thereof. In some examples, each gate layer 411 includes a metal layer, e.g., a tungsten layer. In some implementations, each gate layer 411 includes a doped polysilicon layer. Each gate layer 411 may include a control gate surrounding a memory cell. The gate layer 411 at the top of the stack structure 410 may laterally extend as an upper select gate line (e.g., a top select gate line) 413, the gate layer 411 at the bottom of the stack structure 410 may laterally extend as a lower select gate line (e.g., a bottom select gate line) 414, and the gate layer 411 laterally extending between the upper select gate line and the lower select gate line may serve as a word line layer 403.

In some examples, the stack structure 410 may be disposed on the substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

In some examples, the NAND memory string 308 comprises a channel structure vertically extending through the stack structure 410. In some implementations, the channel structure includes a channel hole filled with one or more semiconductor materials (e.g., as a semiconductor channel) and one or more dielectric materials (e.g., as a memory film). In some implementations, the semiconductor channel includes silicon, e.g., polysilicon. In some implementations, the memory film is a composite dielectric layer that includes a tunneling layer, a storage layer (also referred to as a “charge trap/storage layer”), and a barrier layer. The channel structure may have a cylindrical shape (e.g., a pillar shape). According to some examples, the semiconductor channel, the tunneling layer, the storage layer, and the barrier layer are arranged in this order radially from a center of the pillar toward an outer surface of the pillar. The tunneling layer may include silicon oxide, silicon oxynitride, or any combination thereof. The storage layer may include silicon nitride, silicon oxynitride, or any combination thereof. The barrier layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

Referring back to FIG. 3B, the peripheral circuit 302 can be coupled to the memory array 301 through bit lines 316, word lines 318, source lines 314, BSG lines 315, and TSG lines 313. Peripheral circuit 302 may include any suitable analog, digital, and mixed signal circuit for facilitating operation of memory array 301 by applying voltage and/or current signals to each target memory cell 306 and sensing voltage and/or current signals from each target memory cell 306 via bit lines 316, word lines 318, source lines 314, BSG lines 315, and TSG lines 313. Peripheral circuit 302 may include various types of peripheral circuit formed by using metal-oxide-semiconductor (MOS) technology.

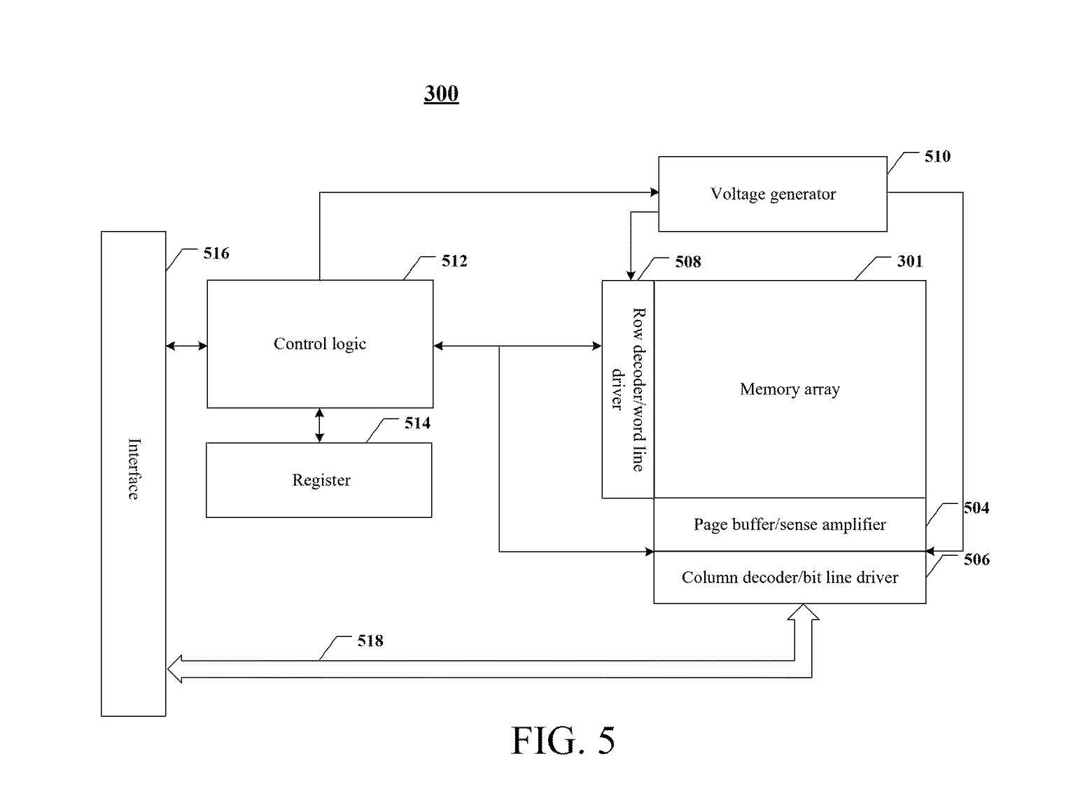

FIG. 5 illustrates a schematic circuit diagram of an example memory 300 including a peripheral circuit and a memory array according to some aspects of the present disclosure. Some example peripheral circuits and memory arrays are shown in FIG. 5, and the peripheral circuit 302 includes a page buffer/sense amplifier 504, a column decoder/bit line driver 506, a row decoder/word line driver 508, a voltage generator 510, a control logic 512, a register 514, an interface 516, and a data bus 518, as illustrated below in combination with FIGS. 3B and 5. It should be understood that in some examples, additional peripheral circuits not shown in FIG. 5 may also be included.

The page buffer/sense amplifiers 504 may be configured to read data from and program (write) data to the memory array 301 according to control signals from the control logic 512. In one example, the page buffer/sense amplifier 504 may store a page of program data (write data) to be programmed into one page 320 of the memory array 301. In another example, the page buffer/sense amplifier 504 can perform a program verify operation to ensure that data has been correctly programmed into the memory cells 306 coupled to the selected word line 318. In yet another example, the page buffer/sense amplifier 504 can also sense a low power signal from the bit line 316 representing a bit of data stored in the memory cell 306 and amplify the small voltage swing to a recognizable logic level in a read operation. The column decoder/bit line driver 506 may be configured to be controlled by the control logic 512 and select one or more NAND memory strings 308 by applying a bit line voltage generated from the voltage generator 510.

The row decoder/word line driver 508 may be configured to be controlled by the control logic 512 and select/deselect the memory blocks 304 of the memory array 301 and select/deselect the word lines 318 of the memory blocks 304. The row decoder/word line driver 508 may also be configured to drive the word lines 318 using word line voltages generated from the voltage generator 510. In some implementations, the row decoder/word line driver 508 can also select/deselect and drive the BSG lines 315 and the TSG lines 313. As described in detail below, the row decoder/word line driver 508 is configured to perform a program operation on the memory cells 306 coupled to one or more selected word lines 318. The voltage generator 510 may be configured to be controlled by the control logic 512 and generate word line voltages (e.g., read voltages, program voltages, pass voltages, local voltages, verify voltages, etc.), bit line voltages, and source line voltages to be supplied to the memory array 301.

In some examples, the program operation may include a plurality of operations, for example, the program operation may include a bit line setting operation, a program execution operation, and a program recovery operation. After the program operation is performed, a program verification operation also needs to be performed; after the program verification operation is performed, a program verification recovery operation also needs to be performed. During the bit line setting operation of the program operation, the voltage may be maintained at the ground voltage GND for unselected word lines. During a program execution operation of a program operation, a pass voltage Vₚₐₛₛ may be applied to unselected word lines and a program voltage V_{pgm} may be applied to the selected word lines. Thus, the memory cells connected to the selected word line may be programmed. In the process of performing the program recovery operation of the program operation, the voltages applied to all the word lines may be reduced to the ground voltage GND.

In a process of performing the program verify operation, a verify voltage V_{vrf} may be applied to a selected word line, and a read voltage V_{read} may be applied to an unselected word line.

In the process of performing the program verify recovery operation, a recovery operation of lowering the voltage to the ground voltage GND may be performed on both the unselected word lines and the selected word lines.

The control logic 512 may be coupled to each peripheral circuit described above and configured to control the operation of each peripheral circuit. The registers 514 may be coupled to the control logic 512 and include status registers, command registers, and address registers for storing status information, command operation codes (OP codes), and command addresses for controlling operations of each peripheral circuit. The interface 516 may be coupled to the control logic 512 and act as a control buffer to buffer and relay control commands received from a host (not shown) to the control logic 512, and to buffer and relay status information received from the control logic 512 to the host. The interface 516 can also be coupled to the column decoder/bit line drivers 506 via the data bus 518 and act as a data input/output (I/O) interface and data buffer to buffer and relay data to or from the memory array 301 or 301.

An erase operation of memory cells in a memory block of a memory device typically involves one or more erase-verify iterations, also referred to as erase cycles. In a full word line erase approach, the memory cells connected to each word line in a memory block are simultaneously erased in an erase-verify iteration, typically followed by a full word line verify in which the memory cells connected to each word line are simultaneously subjected to a verify test in an erase-verify iteration. In the odd-even erase approach, the memory cells connected to the odd word lines are erased separately from the memory cells connected to the even word lines. In one approach, the memory cells connected to the odd word lines are subjected to a verify test separately from the memory cells connected to the even word lines. In the other approach, the memory cells connected to each word line are simultaneously subjected to a verify test in an erase-verify iteration.

Compared with the full word line erase approach, the odd-even erase operation can improve the reliability of the memory cell after data retention. However, the odd-even erase operation may also cause serious degradation of the memory cell and reduced reliability of the memory cell after program/erase cycling. How to optimize the odd-even erase algorithm to take its advantage (for example, improve lateral spreading) and avoid or reduce its side effects (serious vertical charge loss due to the degradation of program/erase cycles) is a problem to be considered currently.

As the feature size of the memory cell decreases, for example, gate width and the size of the gate pitch decrease, the data retention characteristics of the memory cell will become worse and worse. The odd-even erase approach may be a trend, so to maximize the advantage of data retention in the early stage of the program/erase cycle in the odd-even erase approach, it is necessary to improve the problems of serious degradation and poor data retention in the later stage of the program/erase cycle.

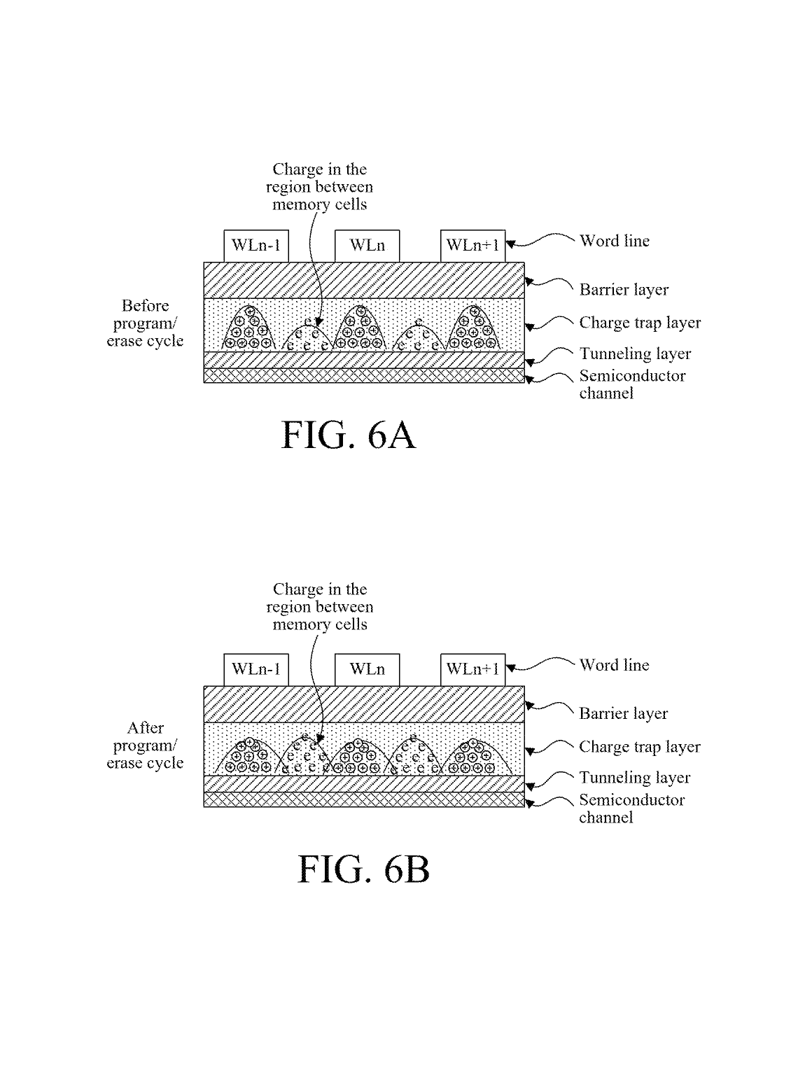

FIGS. 6A and 6B are schematic diagrams of charge distribution of a memory cell before and after a program/erase cycle according to an example of the present disclosure. FIG. 6A is a schematic diagram of charge distribution of a memory cell before a program/erase cycle, and FIG. 6B is a schematic diagram of charge distribution of a memory cell after a program/erase cycle.

Compared with FIG. 6A and referring to FIG. 6B, electrons can be introduced between memory cells by using odd-even erase, thereby improving lateral spreading. For example, on the one hand, a higher pass voltage bias and more electrons in region between memory cells are more conducive to improving the lateral spreading. On the other hand, a higher pass voltage bias and more electrons in region between memory cells requires a higher erase voltage bias/a higher number of program/erase cycles, resulting in the degradation of program/erase cycles and thus more serious vertical charge loss.

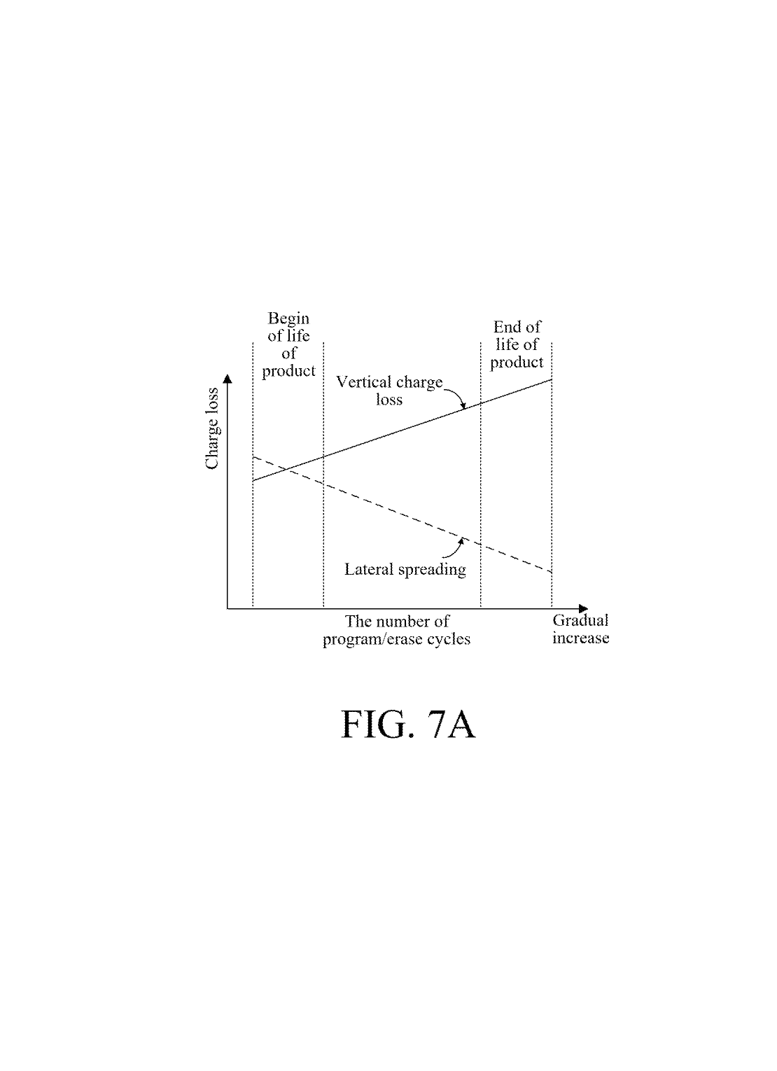

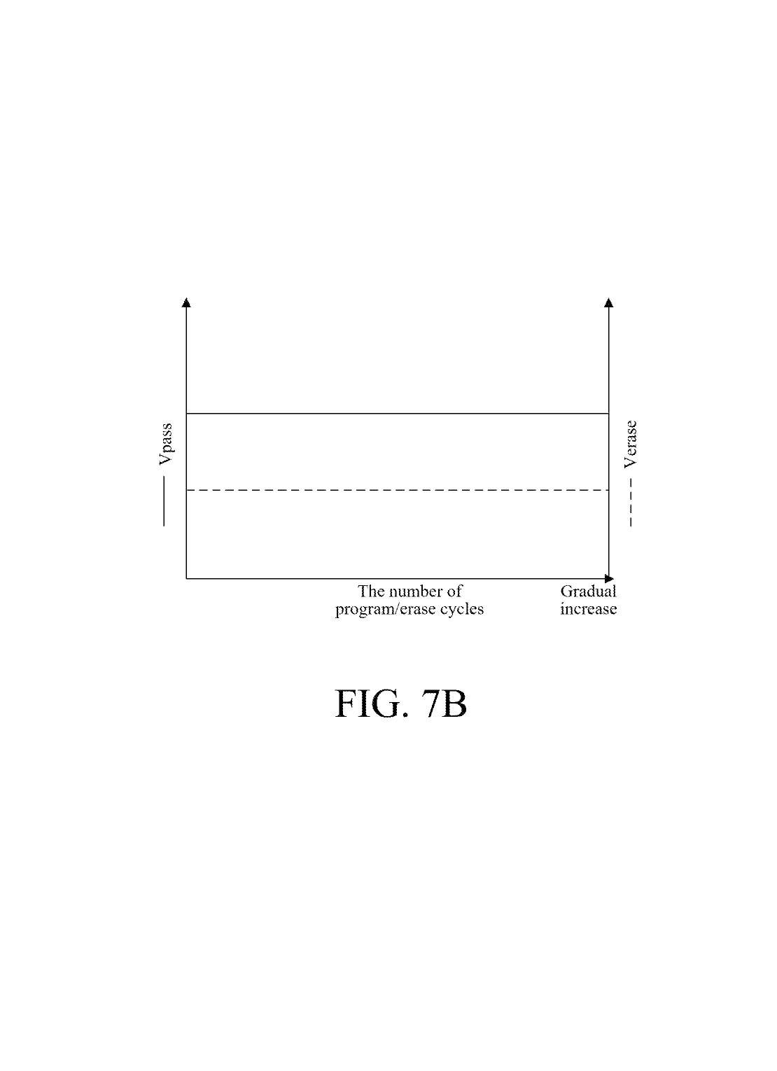

FIG. 7A is a schematic diagram of a relationship between the number of program/erase cycles and charge loss of a memory cell according to an example of the present disclosure.

Referring to FIG. 7A, in consideration of the specific application scenario, when the number of program/erase cycles is relatively small, for example, in a scenario of begin of life (BOL) of product reliability of the memory device, vertical charge loss and lateral spreading are basically equivalent. As the number of program/erase cycles increases, for example, in a scenario of end of life (EOL) of product reliability of the memory device, the tunneling layer of the memory cell degrades, vertical charge loss gradually increases, and lateral spreading gradually decreases because electrons are accumulated in region between memory cells during program/erase cycles.

FIG. 7B is a schematic diagram of an example solution in which the number of program/erase cycles is not associated with a pass voltage Vₚₐₛₛ and an erase voltage Vₑᵣₐₛₑ according to an example of the present disclosure.

Referring to FIG. 7B, different reliability scenarios of life cycles (e.g., BOL/EOL) of the memory device are not associated with the number of program/erase cycles of the memory device. The same odd-even erase approach is applied for different life cycles of the memory device. The pass voltage or the erase voltage is not dynamically adjusted according to the number of program/erase cycles, which fails to give reasonable consideration to requirements of different reliability scenarios of life cycles (e.g., BOL/EOL) of the memory device.

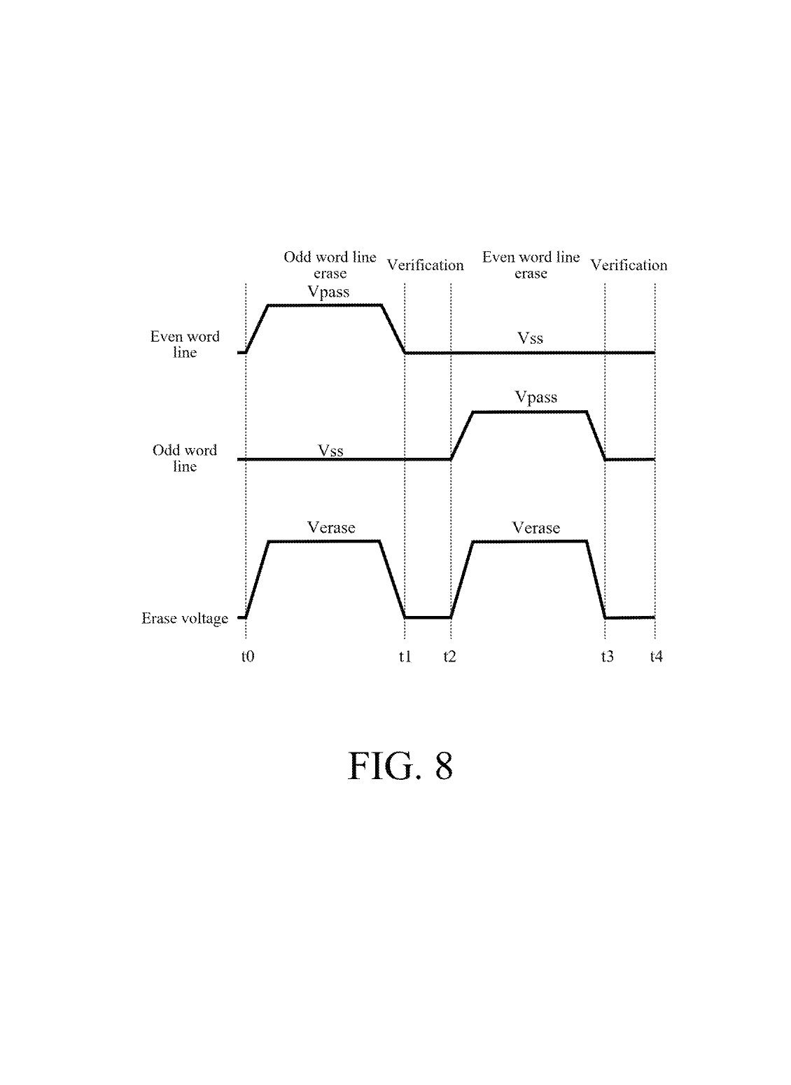

FIG. 8 is a schematic waveform diagram of an odd-even erase operation according to an example of the present disclosure.

Referring to FIG. 8, in one example erase cycle of an odd-even erase operation, performing an odd-even erase operation includes a first erase phase and a second erase phase. The first erase phase of the odd-even erase operation is performed, which corresponds to the phase from time t0 to time t1, that is, the odd word line erase phase. The even word line is applied with a pass voltage Vₚₐₛₛ, the odd word line is applied with a low voltage (for example, a voltage Vₛₛ equal to or close to 0V), and the source line is applied with an erase voltage Vₑᵣₐₛₑ. The phase from time t1 to time t2 is a verify phase corresponding to the odd word line erase phase, and a verify test as a sensing operation may be performed after the erase voltage Vₑᵣₐₛₑ is applied, to determine whether the threshold voltage Vₜₕ of the memory cell coupled to the odd word line has decreased to be lower than the verify voltage V_{vrf} (not shown in FIG. 8). The second erase phase of the odd-even erase operation is performed, which corresponds to the phase from time t2 to time t3, that is, the even word line erase phase. The odd word line is applied with a pass voltage Vₚₐₛₛ, the even word line is applied with a low voltage (for example, a voltage Vₛₛ equal to or close to 0V), and the source line is applied with an erase voltage Vₑᵣₐₛₑ. The phase from time t3 to time t4 is a verify phase corresponding to the even word line erase phase, and a verify test as a sensing operation may be performed after the erase voltage Vₑᵣₐₛₑ is applied, to determine whether the threshold voltage Vₜₕ of the memory cell coupled to the even word line has decreased to be lower than the verify voltage V_{vrf} (not shown in FIG. 8).

Hereinafter, the end of life of the product may be understood as that the number of program/erase cycles of the memory device is close to the total number of program/erase cycles required by the design specification or the total number of theoretical program/erase cycles (the total number of program/erase cycles required by the design specification is generally less than the total number of theoretical program/erase cycles). Accordingly, the begin of life of the product may be understood as that the number of program/erase cycles of the memory device is close to 0. During the product life cycle, as the product life approaches the upper limit, the erase speed and/or write speed, erase performance, etc. of the memory device will gradually decrease, and the erase power consumption, read/write power consumption, etc. will gradually increase. In practical applications, the end of life of the product may also be understood as the erasing speed and/or writing speed of the memory device being close to the erasing speed and/or writing speed required by the design specification. Accordingly, the begin of life of the product may also be understood as program/erase cycle speed of the memory device being higher than the erasing speed and/or writing speed required by the design specification. The end of life of the product may also be understood as the program/erase performance of the memory device being close to the program/erase performance required by the design specification. Accordingly, the begin of life of the product may also be understood as the erasing performance of the memory device being higher than the erase performance required by the design specification, and so on.

In order to reasonably take into account requirements of different reliability scenarios of life cycles (e.g., BOL/EOL) of the memory device, different odd-even erase approaches are performed for memory devices in different life cycles. For example, for the memory cells in the begin of life of the product, higher pass voltage bias and more electrons between the memory cells are more beneficial for improving the lateral spreading, but will also cause more degradation of program/erase cycles in the end of life of the product, which results in more serious vertical charge loss. For example, for the end of life of the product, the lateral spreading of the memory cell is small, and the lateral spreading and the vertical charge loss of the program/erase cycle can be improved by using a relatively low pass voltage bias.

In view of this, examples of the present disclosure provide a memory device, an operation method thereof, and a memory system. The memory device is configured to dynamically reduce the pass voltage (the first pass voltage is reduced to the second pass voltage) or dynamically reduce the erase voltage (the first erase voltage is reduced to the second erase voltage) according to the increase of the number of program/erase cycles (for example, the first number of program/erase cycles is increased to the second number of program/erase cycles), so as to improve the lateral spreading of the memory cell at the begin of life of the product, reduce the degradation of the memory cell at the end of life of the product, reduce the vertical charge loss, maximize the reliability of data retention at the begin of life of the product in the odd-even erase approach, and improve the problems of degradation and deterioration of data retention at the end of life of the product, thereby improving the performance of the full life cycle of the memory device.

According to a first aspect, an example of the present disclosure provides a memory device. The memory device comprises a memory array and a peripheral circuit coupled to the memory array. The peripheral circuit is configured to: during performing a first odd-even erase operation, apply a first erase voltage to a source line, and apply a first pass voltage to a first word line coupled to a first memory cell; and during performing a second odd-even erase operation, apply a second erase voltage to the source line, and apply a second pass voltage to the first word line, where a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

In the examples of the present disclosure, the peripheral circuit is configured to dynamically reduce the pass voltage (the first pass voltage is reduced to the second pass voltage) and/or dynamically reduce the erase voltage (the first erase voltage is reduced to the second erase voltage) according to the increase of the number of program/erase cycles (for example, the first number of program/erase cycles is increased to the second number of program/erase cycles), so as to reduce the degradation of program/erase cycles of the memory device and reduce the vertical charge loss of the memory device.

Hereinafter, the memory device may be understood with reference to the related description of the memory device 104 shown in FIG. 1, FIG. 2A and FIG. 2B, and the memory array and the peripheral circuit may be understood with reference to the related description of the memory array 301 and the peripheral circuit 302 shown in FIG. 3B and FIG. 5, respectively. In some examples, the memory device comprises a three-dimensional NAND memory. The memory cells of the 3D NAND memory include single level cell (SLC), multi level cell (MLC), triple level cell (TLC), and quad level cell (QLC). One memory cell from SLC to QLC can store 1 bit, 2 bits, 3 bits and 4 bits of data, and correspondingly, the voltage states of the NAND memory cell are 2 bits, 4 bits, 8 bits and 16 bits. Since the voltage states from the SLC to the QLC vary from 2 to 16 and there are more different voltage states and higher control difficulty, the programming time becomes longer, the read/write speed decreases, and the voltage state stability decreases, and correspondingly, the theoretical number of program/erase cycles decrease. For example, the theoretical number of program/erase cycles (or the preset number of program/erase cycles) of SLC, MLC, TLC, and QLC may be 100,000, 3000-10000, 500-1000, and 150, respectively. Although the memory cells of the NAND memory may still be usable beyond the theoretical number of program/erase cycles, the stored bit data could be unstable.

Hereinafter, one example erase cycle of the odd-even erase operation includes a first erase phase and a second erase phase, the first erase phase including an odd word line erase phase, and the second erase phase including an even word line erase phase. In an example, performing the first odd-even erase operation may be understood as performing at least one of the odd word line erase stage and the even word line erase stage of the first odd-even erase operation, and performing the second odd-even erase operation may be understood as performing at least one of the odd word line erase stage and the even word line erase stage of the second odd-even erase operation. For example, performing the first odd-even erase operation may be understood as performing an even word line erase phase of the first odd-even erase operation, and performing the second odd-even erase operation may be understood as performing an odd word line erase phase of the second odd-even erase operation. That is, in an example erase cycle of the odd-even erase operation, a corresponding pass voltage in at least one of the first erase stage and the second erase stage may be adjusted, and/or a corresponding erase voltage in at least one of the first erase stage and the second erase stage may be adjusted.

The term “first word line” should be understood to be associated with an even word line erase phase and an odd word line erase phase. For example, in an even word line erase phase of a first odd-even erase operation, a first erase voltage is applied to a source line, and a first pass voltage is applied to a first word line (the term “first word line” here should be understood as an odd word line) coupled to a first memory cell; and in an odd word line erase phase of a second odd-even erase operation, a second erase voltage is applied to the source line, and a second pass voltage is applied to the first word line (the term “first word line” here should be understood as an even word line), where the first pass voltage is greater than the second pass voltage or the first erase voltage is greater than the second erase voltage.

In some examples, the peripheral circuit is configured to: apply the first erase voltage or the second erase voltage to the source line by applying one pulse voltage, or apply the first erase voltage or the second erase voltage to the source line by applying a plurality of step-wise pulse voltages.

In the following description, as an example, the first erase voltage or the second erase voltage is applied to the source line by applying one pulse voltage, but the examples of the present disclosure are not limited thereto. In an example, “applying the first erase voltage or the second erase voltage to the source line by applying one pulse voltage” may be understood alternatively as “applying the first erase voltage or the second erase voltage to the source line by applying a plurality of step-wise pulse voltages”.

In some examples, a corresponding erase voltage (including a first erase voltage or a second erase voltage) is applied to the source line by applying a plurality of step-wise pulse voltages, and the corresponding erase voltage may be understood as an incremental step pulse erase (ISPE) voltage, where a pulse increment of the ISPE voltage corresponding to the first erase voltage is greater than a pulse increment of the ISPE voltage corresponding to the second erase voltage. In an example, the pulse width of the ISPE voltage corresponding to the first erase voltage is greater than the pulse width of the ISPE voltage corresponding to the second erase voltage.

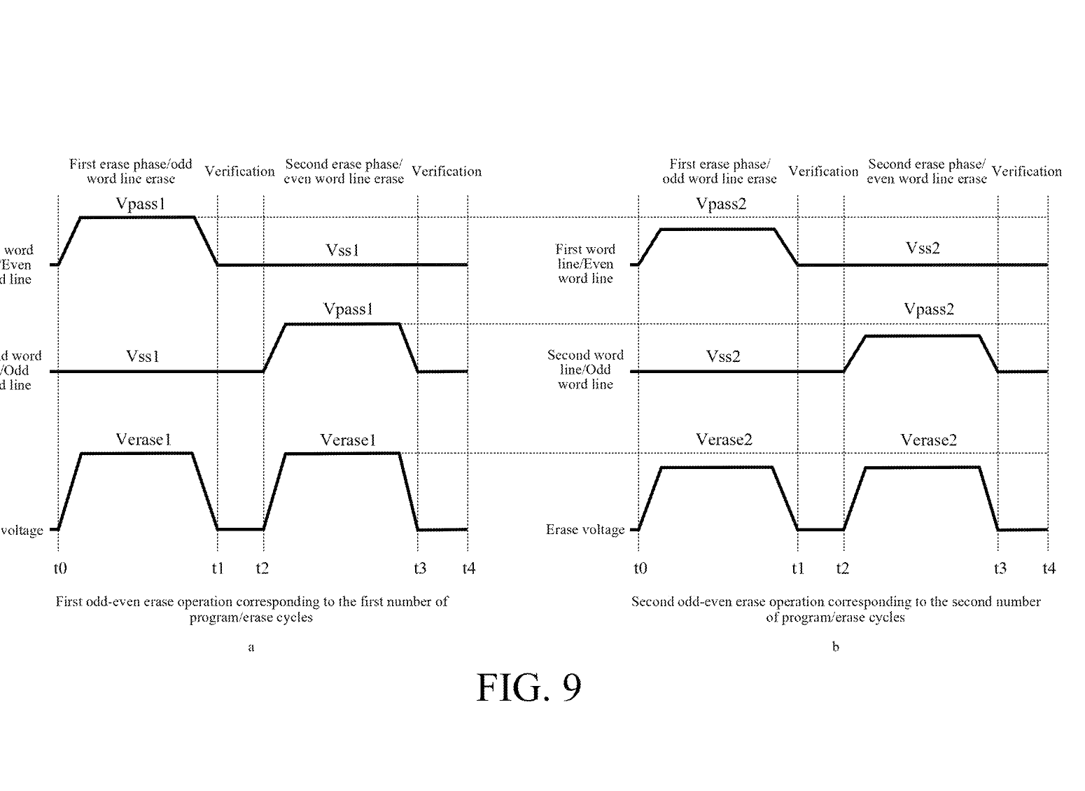

FIG. 9 is a schematic waveform diagram of comparison between a first odd-even erase operation and a second odd-even erase operation according to an example of the present disclosure. FIG. 9 (a) is a waveform diagram of a first odd-even erase operation corresponding to a first number of program/erase cycles, and FIG. 9 (b) is a waveform diagram of a second odd-even erase operation corresponding to a second number of program/erase cycles.

Referring to FIG. 9, in some examples, during performing the first odd-even erase operation, a first erase voltage Vₑᵣₐₛₑ₁ is applied to the source lines, and a first pass voltage Vₚₐₛₛ₁ is applied to the first word lines coupled to the first memory cells; and during performing the second odd-even erase operation, a second erase voltage Vₑᵣₐₛₑ₂ is applied to the source lines, and a second pass voltage Vₚₐₛₛ₂ is applied to the first word lines, where the first pass voltage Vₚₐₛₛ₁ is greater than the second pass voltage Vₚₐₛₛ₂, and the first erase voltage Vₑᵣₐₛₑ₁ is greater than the second erase voltage Vₑᵣₐₛₑ₂.

Referring to FIG. 9, in some examples, the peripheral circuit is configured to: during performing a first odd-even erase operation, apply a first erase inhibit voltage Vₛₛ₁ to a second word line coupled to a second memory cell, the first erase inhibit voltage Vₛₛ₁ being less than a first pass voltage Vₚₐₛₛ₁; and during performing a second odd-even erase operation, apply a second erase inhibit voltage Vₛₛ₂ to the second word line, the second erase inhibit voltage Vₛₛ₂ being less than a second pass voltage Vₚₐₛₛ₂.

In some examples, the first erase inhibit voltage Vₛₛ₁ and the second erase inhibit voltage Vₛₛ₂ may be the same. For example, the first erase inhibit voltage Vₛₛ₁ and the second erase inhibit voltage Vₛₛ₂ are both equal to or close to 0V. In some other examples, the first erase inhibit voltage Vₛₛ₁ and the second erase inhibit voltage Vₛₛ₂ may be different. For example, the first erase inhibit voltage Vₛₛ₁ is equal to 0V, and the second erase inhibit voltage Vₛₛ₂ is close to 0V.

In some examples, referring to FIG. 9 (a), the peripheral circuit is configured to: perform a first erase phase of a first odd-even erase operation, apply a first pass voltage Vₚₐₛₛ₁ to a first word line, apply a first erase inhibit voltage Vₛₛ₁ to a second word line, and apply a first erase voltage Vₑᵣₐₛₑ₁ to a source line; the peripheral circuit is further configured to: perform a second erase phase of the first odd-even erase operation, apply a first pass voltage Vₚₐₛₛ₁ to the second word line, apply a first erase inhibit voltage Vₛₛ₁ to the first word line, and apply a first erase voltage Vₑᵣₐₛₑ₁ to the source line, where the second erase phase of the first odd-even erase operation is different from the first erase phase of the first odd-even erase operation. Referring to FIG. 9 (b), the peripheral circuit is configured to: perform a first erase phase of a second odd-even erase operation, apply a second pass voltage Vₚₐₛₛ₂ to the first word line, apply a second erase inhibit voltage Vₛₛ₂ to the second word line, and apply a second erase voltage Vₑᵣₐₛₑ₂ to the source line; the peripheral circuit is further configured to: perform a second erase phase of the second odd-even erase operation, apply a second pass voltage Vₚₐₛₛ₂ to the second word lines, apply a second erase inhibit voltage Vₛₛ₂ to the first word lines, and apply a second erase voltage Vₑᵣₐₛₑ₂ to the source line, where the second erase phase of the second odd-even erase operation is different from the first erase phase of the second odd-even erase operation.

In one approach, memory cells connected to a first word line/odd word line are subjected to a verify test separately from memory cells connected to a second word line/even word line. For example, the stage from time t1 to time t2 is the verify stage corresponding to the erase stage of the odd word line, and the verify test as the sensing operation may be performed after the erase voltage Vₑᵣₐₛₑ is applied, to determine whether the threshold voltage Vₜₕ of the memory cell coupled to the odd word line has decreased to be lower than the verify voltage V_{vrf} (not shown in FIG. 9); the stage from time t3 to time t4 is the verify stage corresponding to the erase stage of the even word line, and the verify test as the sensing operation may be performed after the erase voltage Vₑᵣₐₛₑ is applied, to determine whether the threshold voltage Vₜₕ of the memory cell coupled to the even word line has decreased to be lower than the verify voltage V_{vrf} (not shown in FIG. 9). In another approach, the memory cells connected to each word line are subjected to a verify test (not shown in FIG. 9) simultaneously in an erase-verify iteration.

It should be noted that although FIG. 9 (b) shows a case in which the pass voltage Vₚₐₛₛ is reduced and the erase voltage Vₑᵣₐₛₑ is reduced according to the number of program/erase cycles, that is, a case in which the first pass voltage Vₚₐₛₛ₁ is greater than the second pass voltage Vₚₐₛₛ₂ and the first erase voltage Vₑᵣₐₛₑ₁ is greater than the second erase voltage Vₑᵣₐₛₑ₂ according to the number of program/erase cycles, the examples of the present disclosure are not limited thereto. In an example, only the pass voltage Vₚₐₛₛ may be reduced according to the number of program/erase cycles, or only the erase voltage Vₑᵣₐₛₑ may be reduced according to the number of program/erase cycles.

In some examples, the peripheral circuit is further configured to: obtain a first number of program/erase cycles; determine a first pass voltage or a first erase voltage according to the first number of program/erase cycles being in a first preset interval of the plurality of preset intervals; obtain a second number of program/erase cycles; and determine a second pass voltage or a second erase voltage according to the second number of program/erase cycles being in a second preset interval of the plurality of preset intervals, each of the preset intervals comprising at least one number of program/erase cycles, and an average value of the preset interval being an average value of each number of program/erase cycles in the preset interval, where the average value of the first preset interval is less than the average value of the second preset interval.

In this example of the present disclosure, the number of program/erase cycles is recorded, a plurality of preset intervals are defined based on a theoretical number of program/erase cycles, and a pass voltage Vₚₐₛₛ (or a negative compensation voltage V_{pass_offset}) is dynamically reduced and/or an erase voltage Vₑᵣₐₛₑ (or a negative compensation voltage V_{erase_offset}) is reduced, according to the number of program/erase cycles being in different preset intervals in the plurality of preset intervals, to reduce degradation of program/erase cycles and reduce vertical charge loss.

In some implementations, the peripheral circuit of the memory device comprises a counting circuit configured to count the number of program/erase cycles.

Here, the preset number of program/erase cycles of the memory device may be the total number of program/erase cycles required by the design specification or the total theoretical number of program/erase cycles. The preset number of program/erase cycles of the memory device is understood as the total number of program/erase cycles of the entire life cycle of the memory device. The plurality of preset intervals may be understood as a part of the preset number of program/erase cycles. Each of the preset intervals comprises at least one number of program/erase cycle, in other words, each of the preset intervals comprises a program/erase cycle range formed by a plurality of numbers of program/erase cycles in the preset number of program/erase cycles. The average value of the preset interval is used to distinguish each preset interval, and the larger the average value of the numbers of program/erase cycles in the preset interval, the larger the average value of the preset interval. In some examples, the number of program/erase cycles included in each preset interval may be the same or different.

It should be noted that, basically, the average value of the preset interval herein is used for assigning values to a plurality of preset intervals to distinguish or represent a plurality of different preset intervals. The average value of the preset interval may be literally understood as an average value obtained by summing values of the numbers of program/erase cycles in the preset interval; or may be interpreted as an average value obtained by summing values of a part of the numbers of program/erase cycles in the preset interval, or a value of a certain number of program/erase cycles in the preset interval (for example, a value of the number of program/erase cycles at an endpoint in the preset interval). In practical applications, the average value of the preset interval may also be assigned with a representative value, for example, the four preset intervals may be represented by values 1, 2, 3, 4, etc.

Hereinafter, the average value of the preset interval is described as the average value obtained by summing the values of the numbers of program/erase cycles in the preset interval, which is only for describing specific examples and is not intended to limit the present disclosure.

In some examples, the peripheral circuit is configured to: define a plurality of preset intervals according to a preset number of program/erase cycles of the memory device, the plurality of preset intervals being M intervals from a first interval to an M^{th} interval, where a number of the M intervals being positively correlated with the preset number of program/erase cycles; and determine that the first pass voltage or the second pass voltage is associated with i or that the first erase voltage or the second erase voltage is associated with i according to the first number of program/erase cycles or the second number of program/erase cycles being in an i^{th} interval, the i^{th} interval being a corresponding first preset interval or a corresponding second preset interval, where M and i are positive integers, M ≥ 2, and M ≥ i ≥ 1.

In an example, the first pass voltage or the second pass voltage is negatively correlated with i, and the first erase voltage or the second erase voltage is negatively correlated with i.

In some examples, the first pass voltage or the second pass voltage satisfies a formula V1-a*(i-1), and the first erase voltage or the second erase voltage satisfies a formula V2-b*(i-1), where V1, a, V1-a*(i-1), V2, b, and V2-b*(i-1) are all positive numbers.

Here, the voltage V1 may be understood as a pass voltage Vₚₐₛₛ, the voltage V2 may be understood as an erase voltage Vₑᵣₐₛₑ, the parameter a is an absolute value of a negative compensation voltage V_{pass_offset} (whose value is a negative number) of the pass voltage Vₚₐₛₛ, the parameter b is an absolute value of a negative compensation voltage V_{erase_offset} (whose value is a negative number) of the erase voltage Vₑᵣₐₛₑ, and the parameter i is any one of the M intervals. In some examples, the parameter a and the parameter b may be empirical values, or may be default values configured when the memory device leaves the factory and obtained through a large number of simulation experiments before the memory device leaves the factory.

In some examples, the number of the plurality of preset intervals is positively correlated with the preset number of program/erase cycles, and the preset number of program/erase cycles may be divided into a plurality of corresponding preset intervals according to the preset number of program/erase cycles. For example, the preset number of program/erase cycles may be divided into 2, 3, 4 or more preset intervals. In practical applications, the preset number of program/erase cycles may be divided into a plurality of appropriate preset intervals according to the characteristics of the threshold voltage distribution from the begin of life of the product to the end of life of the product, so as to adjust the pass voltage or the erase voltage accordingly. In an example, the preset number of program/erase cycles of the memory device is divided into four preset intervals, that is, four preset intervals at the begin of life of the product, at the early stage of life of the product, at the later stage of life of the product, and at the end of life of the product, and the four preset intervals correspond separately to the pass voltage and/or the erase voltage that decrease in sequence.

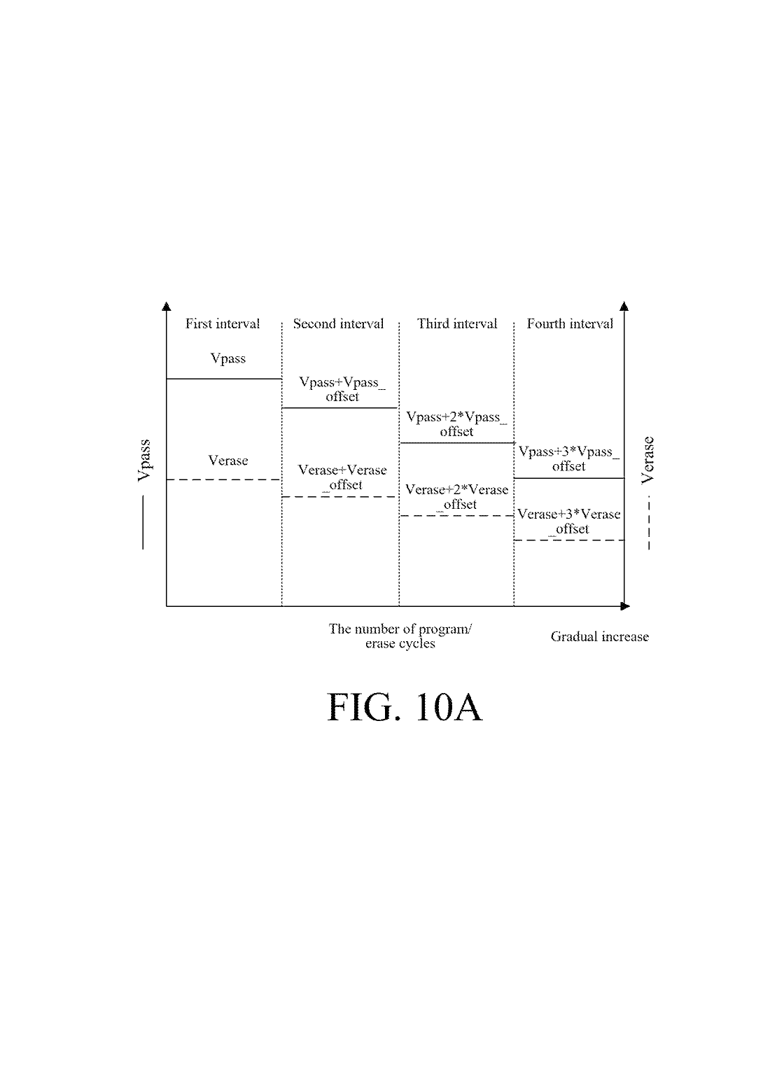

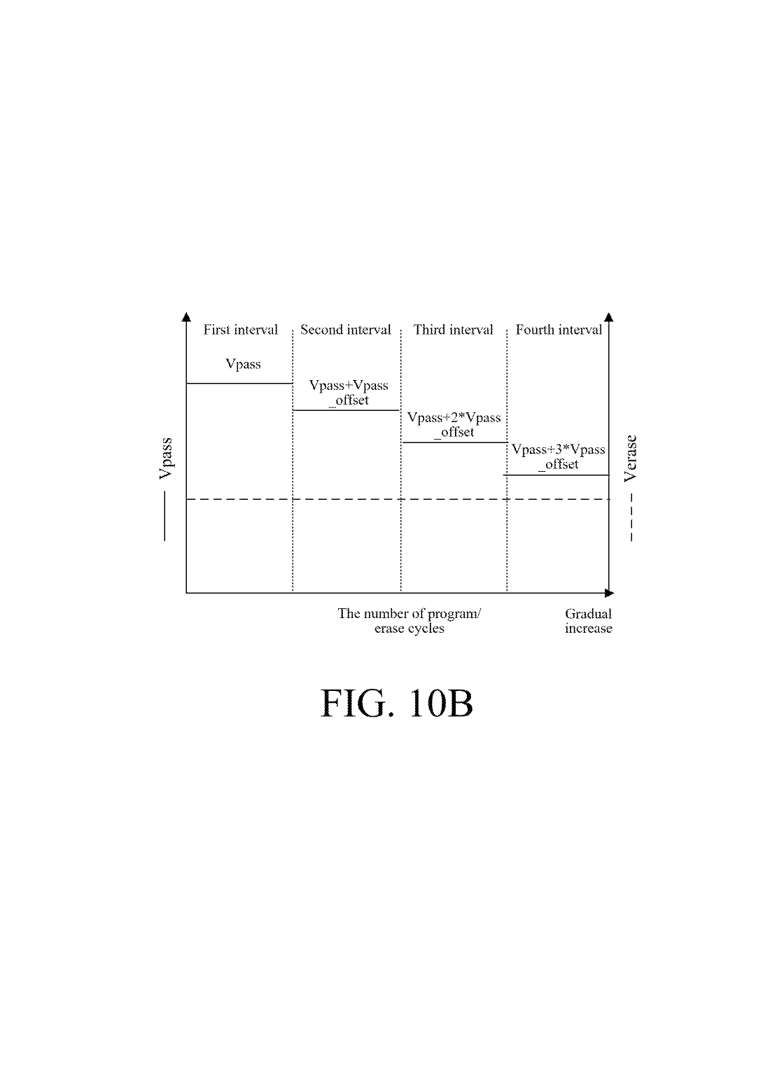

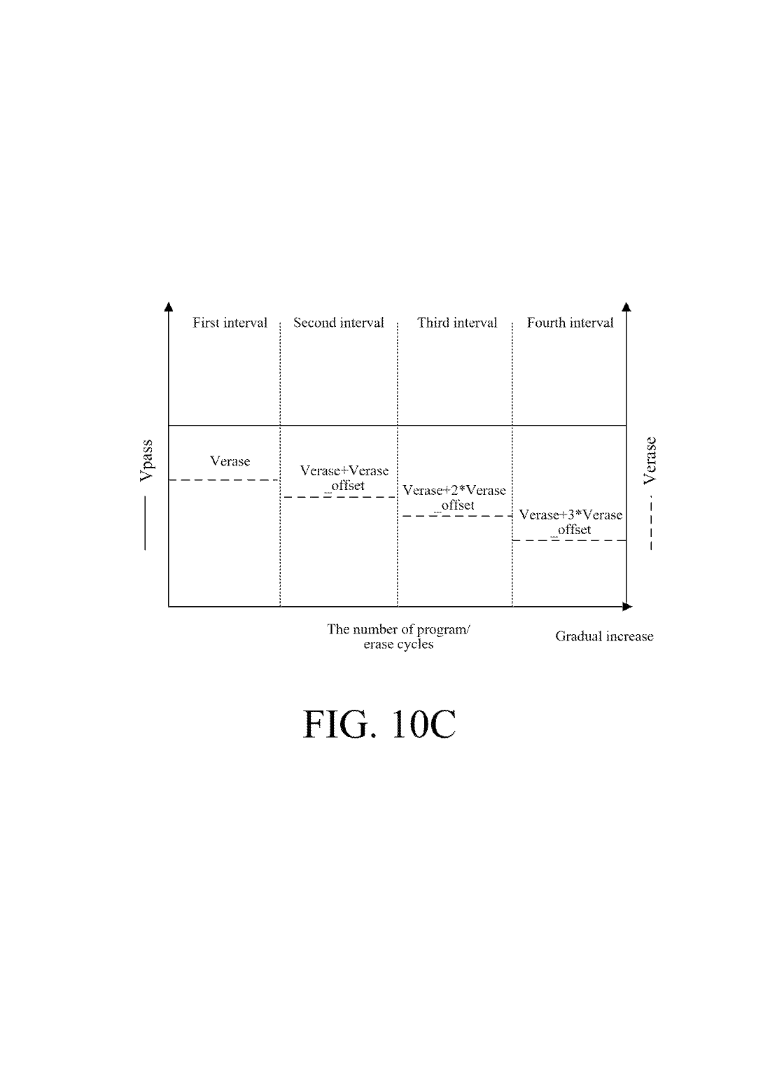

FIG. 10A is a schematic diagram of an example of step-wise reducing the pass voltage Vₚₐₛₛ and the erase voltage Vₑᵣₐₛₑ according to the number of program/erase cycles according to an example of the present disclosure. FIG. 10B is a schematic diagram of an example of step-wise reducing a pass voltage Vₚₐₛₛ according to the number of program/erase cycles according to an example of the present disclosure. FIG. 10C is a schematic diagram of an example of step-wise reducing an erase voltage Vₑᵣₐₛₑ according to the number of program/erase cycles according to an example of the present disclosure.

Referring to FIG. 10A to FIG. 10C, taking the preset number of program/erase cycles of the memory device as 4 thousand times as an example, the preset number of program/erase cycles of the memory device may be divided into 4 intervals, for example, 4 intervals from the first interval to the fourth interval, which are 0 to 1 thousand times (inclusive), 1 to 2 thousand times (inclusive), 2 to 3 thousand times (inclusive), and 3 to 4 thousand times (inclusive) respectively in sequence. Each interval includes at least one number of program/erase cycles, and the larger the average value of the numbers of program/erase cycles in the interval, the larger the average value of the interval. For example, the average value of the first interval to the average value of the fourth interval may be 0.5 thousand times, 1.5 thousand times, 2.5 thousand times, and 3.5 thousand times, respectively. In an example, the average value of the first interval to the average value of the fourth interval may also be represented by values 1 and 2, and 3 and 4, respectively.

Referring to FIG. 10A to FIG. 10C, accordingly, the first interval to the fourth interval correspond to the pass voltage Vₚₐₛₛ, the pass voltage Vₚₐₛₛ+V_{pass_offset}, the pass voltage Vₚₐₛₛ+2*V_{pass_offset}, and the pass voltage Vₚₐₛₛ+3*V_{pass_offset} respectively, and/or the first interval to the fourth interval correspond to the erase voltage Vₑᵣₐₛₑ, the erase voltage Vₑᵣₐₛₑ+V_{erase_offset}, the erase voltage Vₑᵣₐₛₑ+2*V_{erase_offset}, and the erase voltage Vₑᵣₐₛₑ+3*V_{erase_offset} respectively, to reduce the degradation of erase cycles and reduce the vertical charge loss. A negative compensation voltage of the pass voltage Vₚₐₛₛ is V_{pass_offset} (whose value is negative), and a negative compensation voltage of the erase voltage Vₑᵣₐₛₑ is V_{erase_offset} (whose value is negative). In an example, referring to FIG. 10A, according to the first number of program/erase cycles being in the first interval, the first pass voltage applied to the first word line is the pass voltage Vₚₐₛₛ, and the first erase voltage applied to the source line is the erase voltage Vₑᵣₐₛₑ. According to the second number of program/erase cycles number being in the second interval, the second pass voltage applied to the second word line is the pass voltage Vₚₐₛₛ+V_{pass_offset}, and the second erase voltage applied to the source line is the erase voltage Vₑᵣₐₛₑ+V_{erase_offset}.

In some examples, the peripheral circuit is configured to: determine a first pass voltage or a first erase voltage in combination with a first mapping table according to the first number of program/erase cycles being within a first preset interval; and determine a second pass voltage or a second erase voltage in combination with the first mapping table according to the second number of program/erase cycles being in a second preset interval, where the first mapping table comprises a relationship between an average value of each of the plurality of preset intervals and a corresponding pass voltage or a corresponding erase voltage, the corresponding pass voltage comprises the first pass voltage and the second pass voltage, and the corresponding erase voltage comprises the first erase voltage and the second erase voltage.

That is, after obtaining the preset interval in the plurality of preset intervals in which the current number of program/erase cycles (for example, the first number of program/erase cycles or the second number of program/erase cycles) of the memory device is located, the corresponding pass voltage or the corresponding erase voltage may be obtained by querying the first mapping table. In some implementations, the first mapping table may be stored in a register of a peripheral circuit of the memory device.

In some examples, the peripheral circuit is further configured to: obtain a first number of program/erase cycles; determine a first pass voltage or a first erase voltage according to the first number of program/erase cycles; obtain a second number of program/erase cycles; and determine a second pass voltage or a second erase voltage according to the second number of program/erase cycles, where there is a first difference between the first number of program/erase cycles and the second number of program/erase cycles, there is a second difference between the first pass voltage and the second pass voltage, there is a third difference between the first erase voltage and the second erase voltage, and a ratio of the second difference to the first difference is constant, or a ratio of the third difference to the first difference is constant.

In this example of present disclosure, the number of program/erase cycles is recorded, and as the number of program/erase cycles increases, the pass voltage Vₚₐₛₛ is dynamically reduced (or the negative compensation voltage V_{pass_offset}), and/or the erase voltage Vₑᵣₐₛₑ is reduced (or the negative compensation voltage V_{erase_offset}), to reduce the degradation of program/erase cycles and reduce the vertical charge loss.

In some examples, the peripheral circuit is configured to: define N numbers of program/erase cycles from the first program/erase cycle to the N^{th} program/erase cycle according to a preset number of program/erase cycles of the memory device; and determine that the first pass voltage or the second pass voltage is associated with j or that the first erase voltage or the second erase voltage is associated with j according to the first number of program/erase cycles or the second number of program/erase cycles being equal to j program/erase cycles, where N and j are positive integers, N ≥ 2, and N ≥ j ≥ 1.

In an example, the first pass voltage or the second pass voltage is negatively correlated with j, and the first erase voltage or the second erase voltage is negatively correlated with j.

In some examples, the first pass voltage or the second pass voltage satisfies a formula V3−p*(j−1), and the first erase voltage or the second erase voltage satisfies a formula V4−q*(j−1), where V3, p, V3−p*(i−1), V4, q, and V4−q*(i−1) are all positive.

Here, the voltage V3 may be understood as a pass voltage Vₚₐₛₛ, the voltage V4 may be understood as an erase voltage Vₑᵣₐₛₑ, the parameter p is an absolute value of a negative compensation voltage V_{pass_offset} (whose value is negative) of the pass voltage Vₚₐₛₛ, the parameter q is an absolute value of a negative compensation voltage V_{erase_offset} (whose value is negative) of the erase voltage Vₑᵣₐₛₑ, and the parameter j is any one of the N numbers of program/erase cycles.

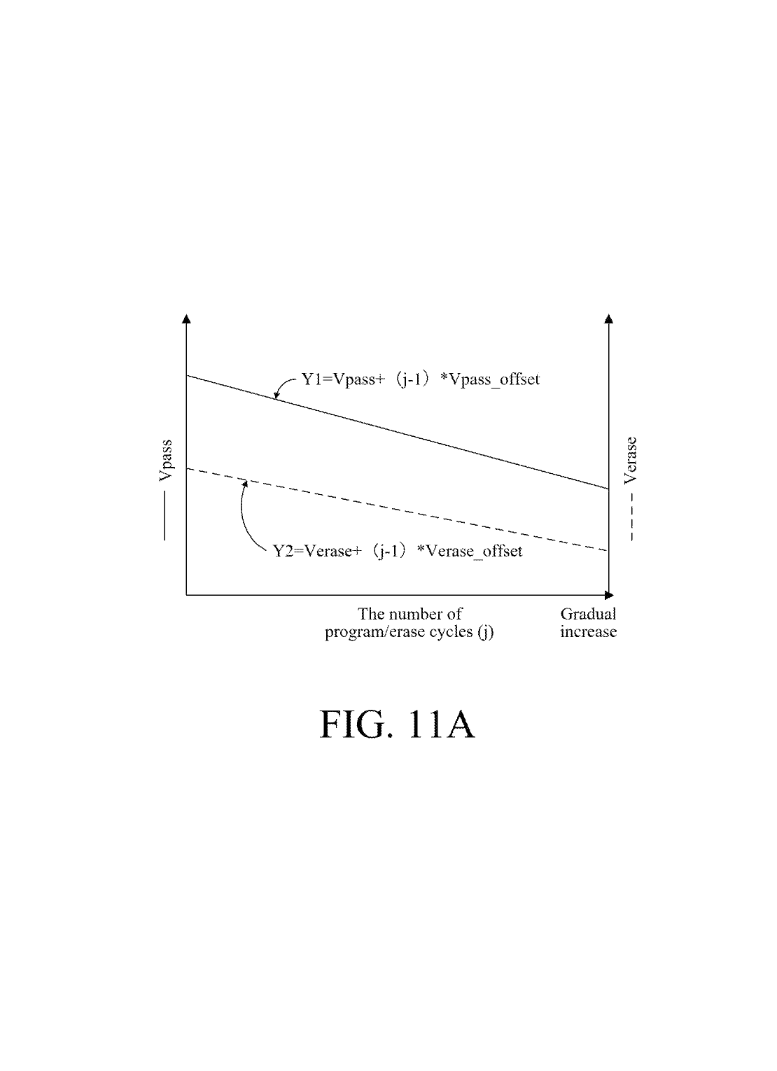

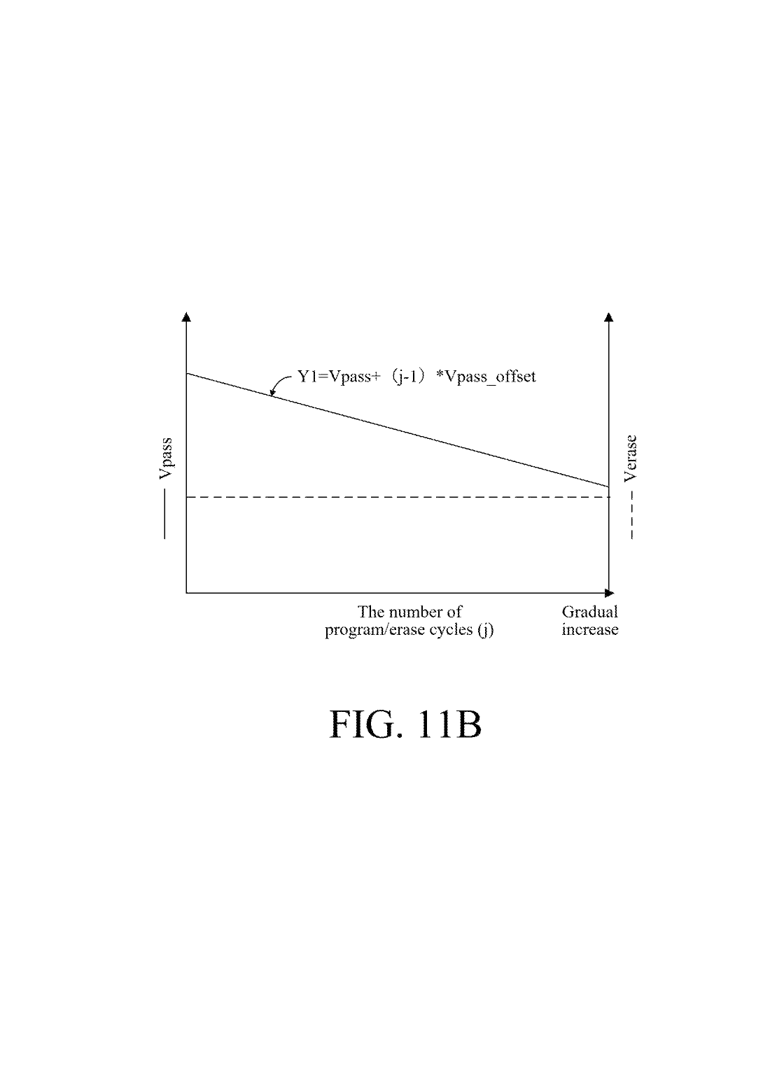

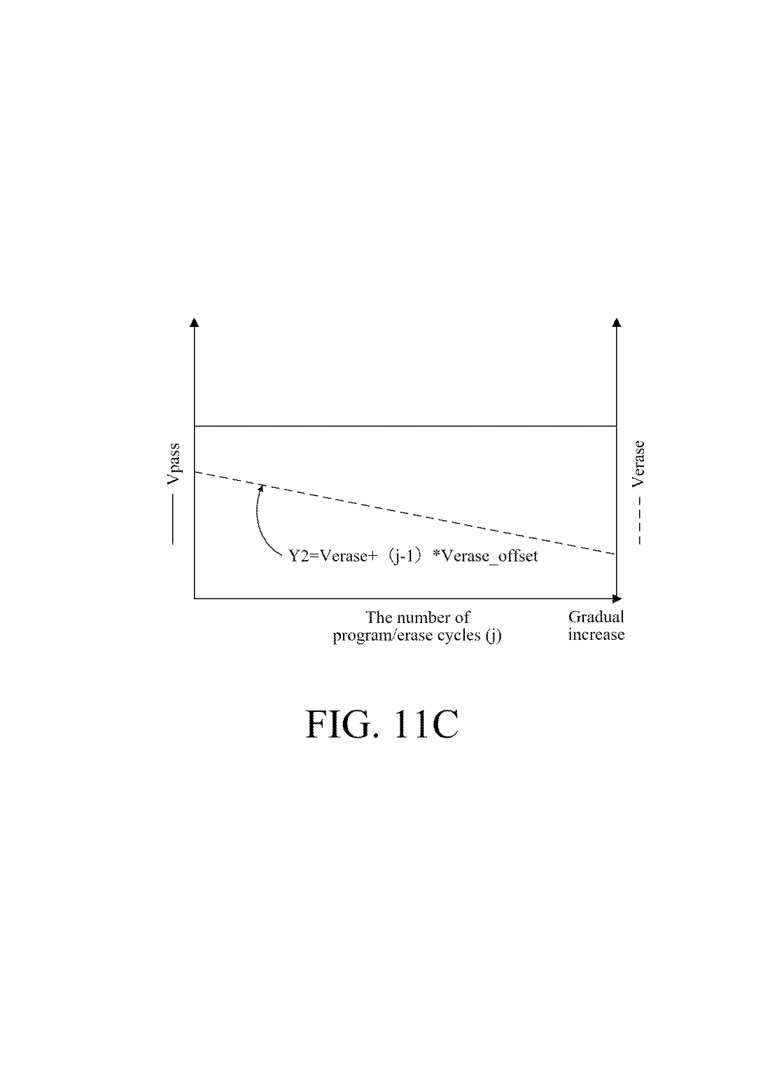

FIG. 11A is a schematic diagram of an example of sequentially reducing a pass voltage Vₚₐₛₛ and sequentially reducing an erase voltage Vₑᵣₐₛₑ according to the number of program/erase cycles according to an example of the present disclosure. FIG. 11B is a schematic diagram of an example of sequentially reducing a pass voltage Vₚₐₛₛ according to the number of program/erase cycles according to an example of the present disclosure. FIG. 11C is a schematic diagram of an example of sequentially reducing an erase voltage Vₑᵣₐₛₑ according to the number of program/erase cycles according to an example of the present disclosure.

Referring to FIG. 11A to FIG. 11C, taking the preset number of program/erase cycles of the memory device as 4 thousand times as an example, accordingly, the pass voltage Y1 corresponding to the j^{th} program/erase cycle is Y1=Vₚₐₛₛ+(j−1)*V_{pass_offset}, and/or the erase voltage Y2 corresponding to the j^{th} program/erase cycle is Y2=Vₑᵣₐₛₑ+(j−1)*V_{erase_offset}, so as to reduce the degradation of program/erase cycles and the vertical charge loss. In an example, referring to FIG. 11A, according to the first number of program/erase cycles being 1000, the first pass voltage applied to the first word line is a pass voltage Y1=Vₚₐₛₛ+999*V_{pass_offset}, and the first erase voltage applied to the source line is an erase voltage Y2=Vₑᵣₐₛₑ+999*V_{erase_offset}; according to the second number of program/erase cycles being 3000, the second pass voltage applied to the second word line is a pass voltage Y1’=Vₚₐₛₛ+2999*V_{pass_offset}, and the second erase voltage applied to the source line is an erase voltage Y2’=Vₑᵣₐₛₑ+2999*V_{erase_offset}.

In some examples, the peripheral circuit is configured to: determine a first pass voltage or a first erase voltage in combination with a second mapping table according to the first number of program/erase cycles; and determine a second pass voltage or a second erase voltage in combination with the second mapping table according to the second number of program/erase cycles, where the second mapping table comprises a relationship between each number of program/erase cycles of a preset number of program/erase cycles of the memory device and a corresponding pass voltage or a corresponding erase voltage, the corresponding pass voltage comprises the first pass voltage and the second pass voltage, and the corresponding erase voltage comprises the first erase voltage and the second erase voltage.

That is, after obtaining the current number of program/erase cycles (for example, the first number of program/erase cycles or the second number of program/erase cycles) of the memory device, the corresponding pass voltage or the corresponding erase voltage may be obtained by querying the second mapping table. In some implementations, the second mapping table can be stored in a register of a peripheral circuit of the memory device.

In the examples of the present disclosure, the peripheral circuit is configured to dynamically reduce the pass voltage (the first pass voltage is reduced to the second pass voltage) or dynamically reduce the erase voltage (the first erase voltage is reduced to the second erase voltage) according to the increase of the number of program/erase cycles (for example, the first number of program/erase cycles is increased to the second number of program/erase cycles), so as to reduce the degradation of program/erase cycles of the memory device and reduce the vertical charge loss of the memory device.

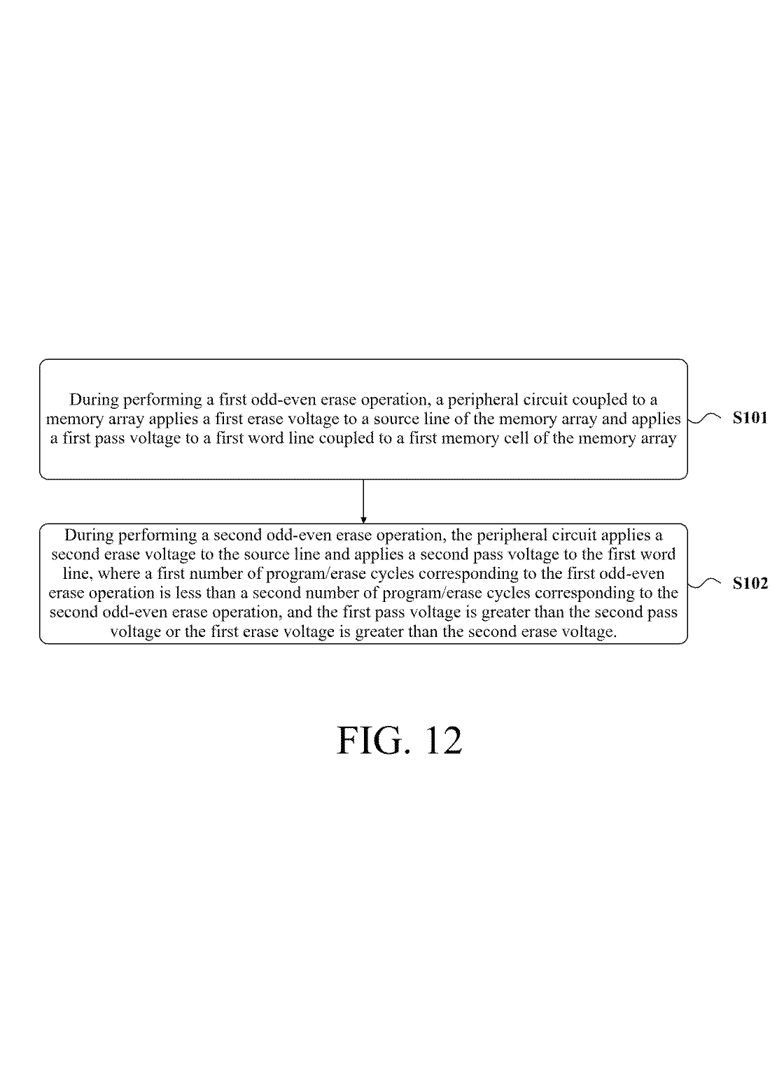

FIG. 12 is a schematic flow diagram of an operation method of a memory device according to an example of the present disclosure.

According to a second aspect, an example of the present disclosure provides an operation method of a memory device, and referring to FIG. 12, the operation method comprises the following operations:

In S101, during performing a first odd-even erase operation, a peripheral circuit coupled to a memory array applies a first erase voltage to a source line of the memory array and applies a first pass voltage to a first word line coupled to a first memory cell of the memory array.

In S102, during performing a second odd-even erase operation, the peripheral circuit applies a second erase voltage to the source line and applies a second pass voltage to the first word line, where a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

In some examples, the operation method further comprises: obtaining a first number of program/erase cycles; determining a first pass voltage or a first erase voltage according to the first number of program/erase cycles being in a first preset interval of the plurality of preset intervals; obtaining a second number of program/erase cycles; and determining a second pass voltage or a second erase voltage according to the second number of program/erase cycles being in a second preset interval of the plurality of preset intervals, where each of the preset intervals comprises at least one number of program/erase cycles, and an average value of the preset interval is an average value of each number of program/erase cycles in the preset interval, and the average value of the first preset interval is less than the average value of the second preset interval.

In some examples, the operation method comprises: defining a plurality of preset intervals according to a preset number of program/erase cycles of the memory device, the plurality of preset intervals being M intervals from a first interval to an M^{th} interval, where the number of the M intervals is positively correlated with the preset number of program/erase cycles; and determining that the first pass voltage or the second pass voltage is associated with i or that the first erase voltage or the second erase voltage is associated with i according to the first number of program/erase cycles or the second number of program/erase cycles being in an i^{th} interval, the i^{th} interval being a corresponding first preset interval or a corresponding second preset interval, where M and i are positive integers, M ≥ 2, and M ≥ i ≥ 1.

In some examples, the operation method comprises: determining a first pass voltage or a first erase voltage in combination with a first mapping table according to the first number of program/erase cycles being in a first preset interval; and determining the second pass voltage or the second erase voltage in combination with the first mapping table according to the second number of program/erase cycles being in a second preset interval, where the first mapping table comprises a relationship between an average value of each of the plurality of preset intervals and a corresponding pass voltage or a corresponding erase voltage, the corresponding pass voltage comprises the first pass voltage and the second pass voltage, and the corresponding erase voltage comprises the first erase voltage and the second erase voltage.

In some examples, the operation method further comprises: obtaining a first number of program/erase cycles; determining a first pass voltage or a first erase voltage according to the first number of program/erase cycles; obtaining a second number of program/erase cycles; and determining a second pass voltage or a second erase voltage according to the second number of program/erase cycles, where there is a first difference between the first number of program/erase cycles and the second number of program/erase cycles, there is a second difference between the first pass voltage and the second pass voltage, there is a third difference between the first erase voltage and the second erase voltage, and a ratio of the second difference to the first difference is constant, or a ratio of the third difference to the first difference is constant.

In some examples, the operation method comprises: defining N numbers of program/erase cycles from a first program/erase cycle to an N^{th} program/erase cycle according to a preset number of program/erase cycles of the memory device; and determining that the first pass voltage or the second pass voltage is associated with j or that the first erase voltage or the second erase voltage is associated with j according to the first number of program/erase cycles or the second number of program/erase cycles being equal to j program/erase cycles, where N and j are positive integers, N ≥ 2, and N ≥ j ≥ 1.

In some examples, the operation method comprises: determining a first pass voltage or a first erase voltage in combination with a second mapping table according to the first number of program/erase cycles; and determining a second pass voltage or a second erase voltage in combination with the second mapping table according to the second number of program/erase cycles, where the second mapping table comprises a relationship between each number of program/erase cycles of a preset number of program/erase cycles of the memory device and a corresponding pass voltage or a corresponding erase voltage, the corresponding pass voltage comprises the first pass voltage and the second pass voltage, and the corresponding erase voltage comprises the first erase voltage and the second erase voltage.

In some examples, the operation method comprises: applying a first erase inhibit voltage to a second word line coupled to a second memory cell during performing a first odd-even erase operation, the first erase inhibit voltage being less than the first pass voltage; and applying a second erase inhibit voltage to the second word line during performing a second odd-even erase operation, the second erase inhibit voltage being less than the second pass voltage.

In some examples, the operation method comprises: performing a first erase phase of a first odd-even erase operation, applying a first pass voltage to a first word line, applying a first erase inhibit voltage to a second word line, and applying a first erase voltage to a source line; the operation method further comprises: performing a second erase phase of the first odd-even erase operation, applying a first pass voltage to the second word line, applying a first erase inhibit voltage to the first word line, and applying a first erase voltage to the source line, where the second erase phase of the first odd-even erase operation is different from the first erase phase of the first odd-even erase operation; the operation method comprises: performing a first erase phase of a second odd-even erase operation, applying a second pass voltage to the first word line, applying a second erase inhibit voltage to the second word line, and applying a second erase voltage to the source line. The operation method further comprises: performing a second erase phase of a second odd-even erase operation, applying a second pass voltage to the second word line, applying a second erase inhibit voltage to the first word line, and applying a second erase voltage to the source line, the second erase phase of the second odd-even erase operation being different from the first erase phase of the second odd-even erase operation.

In some examples, the operation method comprises: applying the first erase voltage or the second erase voltage to the source line by applying one pulse voltage, or applying the first erase voltage or the second erase voltage to the source line by applying a plurality of step pulse voltages.

The memory device used in the operation method of the memory device provided by the example of the present application is the same as or similar to the memory device in the examples of the first aspect. For the technical features not disclosed in detail in the examples of the present disclosure, reference is made for the memory device in the examples of the first aspect for understanding, and details will not be repeated herein.

According to a third aspect, an example of the present disclosure provides a memory system, where the memory system comprises: one or more memory devices provided in the first aspect, and a memory controller coupled with the memory device and controlling the memory device.

Here, for the specific structure and composition of the memory system, reference may be made to the related structure and composition of the memory system 102 in FIG. 1, FIG. 2A, and FIG. 2B, and details will not be repeated herein.

It should be understood that “one example” or “an example” throughout the specification means that particular features, structures, or characteristics related to the example are included in at least one example of the present disclosure. Therefore, “in one example” or “in an example” throughout the specification does not necessarily refer to the same example. Furthermore, the particular features, structures, or characteristics may be combined in any suitable manner in one or more examples. It should be understood that, in various examples of the present disclosure, sequence numbers of the foregoing processes do not indicate an execution sequence, and the execution sequence of the processes should be determined based on functions and internal logic of the processes, and should not constitute any limitation on an implementation process of the examples of the present disclosure. The sequence numbers of the foregoing examples of the present disclosure are merely for description, and do not represent the advantages and disadvantages of the examples.

Examples of the present disclosure provide a memory device, an operation method thereof, and a memory system.

According to a first aspect, an example of the present disclosure provides a memory device, where the memory device comprises a memory array and a peripheral circuit coupled to the memory array, and the peripheral circuit is configured to: apply a first erase voltage to a source line and apply a first pass voltage to a first word line coupled to a first memory cell during performing a first odd-even erase operation; and apply a second erase voltage to the source line and apply a second pass voltage to the first word line during performing a second odd-even erase operation, where a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

In some examples, the peripheral circuit is further configured to: obtain a first number of program/erase cycles; determine a first pass voltage or a first erase voltage according to the first number of program/erase cycles being in a first preset interval of the plurality of preset intervals; obtain a second number of program/erase cycles; and determine a second pass voltage or a second erase voltage according to the second number of program/erase cycles being in a second preset interval of the plurality of preset intervals, each of the preset intervals comprising at least one number of program/erase cycles, and an average value of the preset interval being an average value of each number of program/erase cycles in the preset interval, where the average value of the first preset interval is less than the average value of the second preset interval.

In some examples, the peripheral circuit is configured to: define a plurality of preset intervals according to a preset number of program/erase cycles of the memory device, the plurality of preset intervals being M intervals from a first interval to an M^{th} interval, where a number of the M intervals is positively correlated with the preset number of program/erase cycles; and determine that the first pass voltage or the second pass voltage is associated with i or that the first erase voltage or the second erase voltage is associated with i according to the first number of program/erase cycles or the second number of program/erase cycles being in an i^{th} interval that is a corresponding one of the first preset interval or the second preset interval, where M and i are positive integers, M ≥ 2, M ≥ i ≥ 1.

In some examples, the first pass voltage or the second pass voltage satisfies a formula V1-a*(i−1), and the first erase voltage or the second erase voltage satisfies a formula V2-b*(i−1), where V1, a, V1-a*(i−1), V2, b, and V2-b*(i−1) are all positive.

In some examples, the peripheral circuit is configured to: determine, in combination with a first mapping table, a first pass voltage or a first erase voltage according to the first number of program/erase cycles being in a first preset interval; and determine, in combination with the first mapping table, a second pass voltage or a second erase voltage according to the second number of program/erase cycles being in a second preset interval, where the first mapping table comprises a relationship between an average value of each of the plurality of preset intervals and a corresponding pass voltage or a corresponding erase voltage, the corresponding pass voltage comprises the first pass voltage and the second pass voltage, and the corresponding erase voltage comprises the first erase voltage and the second erase voltage.

In some examples, the peripheral circuit is further configured to: obtain a first number of program/erase cycles; determine a first pass voltage or a first erase voltage according to the first number of program/erase cycles; obtain a second number of program/erase cycles; and determine a second pass voltage or a second erase voltage according to the second number of program/erase cycles, where there is a first difference between the first number of program/erase cycles and the second number of program/erase cycles, there is a second difference between the first pass voltage and the second pass voltage, there is a third difference between the first erase voltage and the second erase voltage, and a ratio of the second difference to the first difference is constant, or a ratio of the third difference to the first difference is constant.

In some examples, the peripheral circuit is configured to: define N numbers of program/erase cycles from the first program/erase cycle to the N^{th} program/erase cycle according to a preset number of program/erase cycles of the memory device; and determine that the first pass voltage or the second pass voltage is associated with j or that the first erase voltage or the second erase voltage is associated with j according to the first number of program/erase cycles or the second number of program/erase cycles being a j^{th} program/erase cycle, where N and j are positive integers, N ≥ 2, and N ≥ j ≥ 1.

In some examples, the first pass voltage or the second pass voltage satisfies a formula V3−p*(j−1), and the first erase voltage or the second erase voltage satisfies a formula V4−q*(j−1), where V3, p, V3−p*(i−1), V4, q, and V4−q*(i−1) are all positive.

In some examples, the peripheral circuit is configured to: determine a first pass voltage or a first erase voltage in combination with a second mapping table according to the first number of program/erase cycles; and determine a second pass voltage or a second erase voltage in combination with the second mapping table according to the second number of program/erase cycles, where the second mapping table comprises a relationship between each number of program/erase cycles of a preset number of program/erase cycles of the memory device and a corresponding pass voltage or a corresponding erase voltage, the corresponding pass voltage comprises the first pass voltage and the second pass voltage, and the corresponding erase voltage comprises the first erase voltage and the second erase voltage.

In some examples, the peripheral circuit is configured to: apply a first erase inhibit voltage to a second word line coupled to a second memory cell during performing a first odd-even erase operation, the first erase inhibit voltage being less than the first pass voltage; and apply a second erase inhibit voltage to the second word line during performing a second odd-even erase operation, the second erase inhibit voltage being less than the second pass voltage.

In some examples, the peripheral circuit is configured to: perform a first erase phase of the first odd-even erase operation, apply a first pass voltage to the first word line, apply a first erase inhibit voltage to the second word line, and apply a first erase voltage to the source line; the peripheral circuit is further configured to: perform a second erase phase of the first odd-even erase operation, apply a first pass voltage to the second word line, apply a first erase inhibit voltage to the first word line, and apply a first erase voltage to the source line; the second erase phase of the first odd-even erase operation is different from the first erase phase of the first odd-even erase operation; the peripheral circuit is configured to: perform a first erase phase of the second odd-even erase operation, apply a second pass voltage to the first word line, apply a second erase inhibit voltage to the second word line, and apply a second erase voltage to the source line; the peripheral circuit is further configured to: perform a second erase phase of the second odd-even erase operation, apply a second pass voltage to the second word line, apply a second erase inhibit voltage to the first word line, and apply a second erase voltage to the source line; and the second erase phase of the second odd-even erase operation is different from the first erase phase of the second odd-even erase operation.

According to a second aspect, an example of the present disclosure provides an operation method of a memory device, where the operation method comprises: during performing a first odd-even erase operation, applying, by a peripheral circuit coupled to a memory array, a first erase voltage to a source line of the memory array, and applying, by the peripheral circuit, a first pass voltage to a first word line coupled to a first memory cell of the memory array; and during performing a second odd-even erase operation, applying, by the peripheral circuit, a second erase voltage to the first word line, where a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

In some examples, the operation method further comprises: obtaining a first number of program/erase cycles; determining a first pass voltage or a first erase voltage according to the first number of program/erase cycles being in a first preset interval of the plurality of preset intervals; obtaining a second number of program/erase cycles; and determining a second pass voltage or a second erase voltage according to the second number of program/erase cycles being in a second preset interval of the plurality of preset intervals, where each of the preset intervals comprises at least one number of program/erase cycles, an average value of the preset interval is an average value of each number of program/erase cycles in the preset interval, and the average value of the first preset interval is less than the average value of the second preset interval.

In some examples, the operation method comprises: defining a plurality of preset intervals according to a preset number of program/erase cycles of the memory device, the plurality of preset intervals being M intervals from a first interval to an M^{th} interval, where the number of the M intervals is positively correlated with the preset number of program/erase cycles; and determining that the first pass voltage or the second pass voltage is associated with i or that the first erase voltage or the second erase voltage is associated with i according to the first number of program/erase cycles or the second number of program/erase cycles being in an i^{th} interval that is a corresponding one of the first preset interval or the second preset interval, where M and i are positive integers, M ≥ 2, and M ≥ i ≥ 1.

In some examples, the operation method comprises: determining a first pass voltage or a first erase voltage in combination with a first mapping table according to the first number of program/erase cycles being in a first preset interval; and determining the second pass voltage or the second erase voltage in combination with the first mapping table according to the second number of program/erase cycles being in a second preset interval, where the first mapping table comprises a relationship between an average value of each of the plurality of preset intervals and a corresponding pass voltage or a corresponding erase voltage, the corresponding pass voltage comprises the first pass voltage and the second pass voltage, and the corresponding erase voltage comprises the first erase voltage and the second erase voltage.

In some examples, the operation method further comprises: obtaining a first number of program/erase cycles; determining a first pass voltage or a first erase voltage according to the first number of program/erase cycles; obtaining a second number of program/erase cycles; and determining a second pass voltage or a second erase voltage according to the second number of program/erase cycles, where there is a first difference between the first number of program/erase cycles and the second number of program/erase cycles, there is a second difference between the first pass voltage and the second pass voltage, there is a third difference between the first erase voltage and the second erase voltage, and a ratio of the second difference to the first difference is constant, or a ratio of the third difference to the first difference is constant.

In some examples, the operation method comprises: defining N numbers of program/erase cycles from a first program/erase cycle to an N^{th} program/erase cycle according to a preset number of program/erase cycles of the memory device; and determining that the first pass voltage or the second pass voltage is associated with j or that the first erase voltage or the second erase voltage is associated with j according to the first number of program/erase cycles or the second number of program/erase cycles being a j^{th} program/erase cycle, where N and j are positive integers, N ≥ 2, and N ≥ j ≥ 1.

In some examples, the operation method comprises: determining a first pass voltage or a first erase voltage in combination with a second mapping table according to the first number of program/erase cycles; and determining a second pass voltage or a second erase voltage in combination with the second mapping table according to the second number of program/erase cycles, where the second mapping table comprises a relationship between each number of program/erase cycles of a preset number of program/erase cycles of the memory device and a corresponding pass voltage or a corresponding erase voltage, the corresponding pass voltage comprises the first pass voltage and the second pass voltage, and the corresponding erase voltage comprises the first erase voltage and the second erase voltage.

In some examples, the operation method comprises: applying a first erase inhibit voltage to a second word line coupled to a second memory cell during performing a first odd-even erase operation, the first erase inhibit voltage being less than the first pass voltage; and applying a second erase inhibit voltage to the second word line during performing a second odd-even erase operation, the second erase inhibit voltage being less than the second pass voltage.

In some examples, the operation method comprises: performing a first erase phase of a first odd-even erase operation, applying a first pass voltage to a first word line, applying a first erase inhibit voltage to a second word line, and applying a first erase voltage to a source line; the operation method further comprises: performing a second erase phase of the first odd-even erase operation, applying a first pass voltage to the second word line, applying a first erase inhibit voltage to the first word line, and applying a first erase voltage to the source line, where the second erase phase of the first odd-even erase operation is different from the first erase phase of the first odd-even erase operation; the operation method comprises: performing a first erase phase of a second odd-even erase operation, applying a second pass voltage to the first word line, applying a second erase inhibit voltage to the second word line, and applying a second erase voltage to the source line; the operation method further comprises: performing a second erase phase of the second odd-even erase operation, applying a second pass voltage to the second word line, applying a second erase inhibit voltage to the first word line, and applying a second erase voltage to the source line, where the second erase phase of the second odd-even erase operation is different from the first erase phase of the second odd-even erase operation.

According to a third aspect, an example of the present disclosure provides a memory system, where the memory system comprises: one or more memory devices provided in the first aspect, and a memory controller coupled with the memory device and controlling the memory device.

In the examples of the present disclosure, the peripheral circuit is configured to dynamically reduce the pass voltage (e.g., the first pass voltage is reduced to the second pass voltage) or dynamically reduce the erase voltage (e.g., the first erase voltage is reduced to the second erase voltage) according to the increase of the number of program/erase cycles (e.g., the first number of program/erase cycles is increased to the second number of program/erase cycles), so as to reduce the degradation of program/erase cycles of the memory device and reduce the vertical charge loss.

The above description is only some implementations of this disclosure, and it does not limit the scope of protection of this disclosure. Any equivalent structure modification made according to the specification and drawings of this disclosure or direct or indirect application in other related technical fields under the disclosed examples of this disclosure is included in the scope of protection of this disclosure.

What is claimed is:

1. A memory device, comprising a memory array and a peripheral circuit coupled to the memory array, wherein the peripheral circuit is configured to:
during a first odd-even erase operation:
apply a first erase voltage to a source line; and
apply a first pass voltage to a first word line coupled to a first memory cell; and
during a second odd-even erase operation;
apply a second erase voltage to the source line; and
apply a second pass voltage to the first word line,
wherein a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

2. The memory device of claim 1, wherein the peripheral circuit is further configured to:
obtain the first number of program/erase cycles;
determine the first pass voltage or the first erase voltage based on the first number of program/erase cycles being in a first preset interval of a plurality of preset intervals;
obtain the second number of program/erase cycles; and
determine the second pass voltage or the second erase voltage based on the second number of program/erase cycles being in a second preset interval of the plurality of preset intervals,
wherein a first average value of the first preset interval is an average of a plurality of numbers of program/erase cycles in the first preset interval, and wherein the first average value of the first preset interval is less than a second average value of the second preset interval.

3. The memory device of claim 2, wherein the peripheral circuit is configured to:
define the plurality of preset intervals according to a preset number of program/erase cycles of the memory device, the plurality of preset intervals being M intervals, wherein a number of the M intervals is positively correlated with the preset number of program/erase cycles; and
determine:
that the first pass voltage or the second pass voltage is associated with an i^{th} interval based on the i^{th} interval being the first preset interval of the first number of program/erase cycles, or
that the first erase voltage or the second erase voltage is associated with the i^{th} interval based on the i^{th} interval being the second preset interval of the second number of program/erase cycles, wherein M and i are positive integers, M ≥ 2, and M ≥ i ≥ 1.

4. The memory device of claim 3, wherein the first pass voltage or the second pass voltage satisfies a formula V1-a*(i−1), and the first erase voltage or the second erase voltage satisfies a formula V2-b*(i−1), and wherein V1, a, V1-a*(i−1), V2, b, and V2-b*(i−1) are positive.

5. The memory device of claim 2, wherein the peripheral circuit is configured to:
determine, in combination with a first mapping table, the first pass voltage or the first erase voltage based on the first number of program/erase cycles being in the first preset interval; and
determine, in combination with the first mapping table, the second pass voltage or the second erase voltage based on the second number of program/erase cycles being in the second preset interval,
wherein the first mapping table comprises a relationship between:
an average of the plurality of preset intervals and a corresponding one of the first pass voltage or the second pass voltage, or
an average of the plurality of preset intervals and a corresponding one of the first erase voltage or the second erase voltage.

6. The memory device of claim 1, wherein the peripheral circuit is further configured to:
determine the first pass voltage or the first erase voltage based on the first number of program/erase cycles; and
determine the second pass voltage or the second erase voltage based on the second number of program/erase cycles,
wherein there is a first difference between the first number of program/erase cycles and the second number of program/erase cycles, there is a second difference between the first pass voltage and the second pass voltage, there is a third difference between the first erase voltage and the second erase voltage, and wherein:
a ratio of the second difference to the first difference is constant, or
a ratio of the third difference to the first difference is constant.

7. The memory device of claim 6, wherein the peripheral circuit is configured to:
define N numbers of program/erase cycles based on a preset number of program/erase cycles of the memory device; and
determine:
that the first pass voltage or the second pass voltage is associated with j program/erase cycles based on the first number of program/erase cycles being equal to the j program/erase cycles, or
that the first erase voltage or the second erase voltage is associated with the j program/erase cycles based on the second number of program/erase cycles being equal to the j program/erase cycles, wherein N and j are positive integers, N ≥ 2, and N ≥ j ≥ 1.

8. The memory device of claim 7, wherein the first pass voltage or the second pass voltage satisfies a formula V3−p*(j−1), and the first erase voltage or the second erase voltage satisfies a formula V4−q*(j−1), and wherein N and j are positive integers, N ≥ 2, N ≥ j ≥ 1, and V3, p, V3−p*(i−1), V4, q, and V4−q*(i−1) are positive.

9. The memory device of claim 6, wherein the peripheral circuit is configured to:
determine, in combination with a second mapping table, the first pass voltage or the first erase voltage based on the first number of program/erase cycles; and
determine, in combination with the second mapping table, the second pass voltage or the second erase voltage based on the second number of program/erase cycles,
wherein the second mapping table comprises a relationship between each number of program/erase cycles of the memory device and a corresponding one of the first pass voltage or the second pass voltage or a corresponding one of the first erase voltage or the second erase voltage.

10. The memory device of claim 1, wherein the peripheral circuit is configured to:
apply a first erase inhibit voltage to a second word line coupled to a second memory cell during the first odd-even erase operation, the first erase inhibit voltage being less than the first pass voltage; and
apply a second erase inhibit voltage to the second word line during the second odd-even erase operation, the second erase inhibit voltage being less than the second pass voltage.

11. The memory device of claim 10, wherein
the peripheral circuit is configured to: perform a first erase phase of the first odd-even erase operation, apply the first pass voltage to the first word line, apply the first erase inhibit voltage to the second word line, and apply the first erase voltage to the source line;
the peripheral circuit is further configured to: perform a second erase phase of the first odd-even erase operation, apply the first pass voltage to the second word line, apply the first erase inhibit voltage to the first word line, and apply the first erase voltage to the source line, wherein the second erase phase of the first odd-even erase operation is different from the first erase phase of the first odd-even erase operation;
the peripheral circuit is configured to: perform a first erase phase of the second odd-even erase operation, apply the second pass voltage to the first word line, apply the second erase inhibit voltage to the second word line, and apply the second erase voltage to the source line; and
the peripheral circuit is further configured to: perform a second erase phase of the second odd-even erase operation, apply the second pass voltage to the second word line, apply the second erase inhibit voltage to the first word line, and apply the second erase voltage to the source line, wherein the second erase phase of the second odd-even erase operation is different from the first erase phase of the second odd-even erase operation.

12. A method of a memory device, the method comprising:
during a first odd-even erase operation, applying, by a peripheral circuit coupled to a memory array:
a first erase voltage to a source line of the memory array, and
a first pass voltage to a first word line coupled to a first memory cell of the memory array; and
during a second odd-even erase operation, applying, by the peripheral circuit:
a second erase voltage to the source line, and
a second pass voltage to the first word line,
wherein a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage.

13. The method of claim 12, further comprising:
obtaining the first number of program/erase cycles;
determining the first pass voltage or the first erase voltage based on the first number of program/erase cycles being in a first preset interval of a plurality of preset intervals;
obtaining the second number of program/erase cycles; and
determining the second pass voltage or the second erase voltage based on the second number of program/erase cycles being in a second preset interval of the plurality of preset intervals,
wherein each of the preset intervals comprises a number of program/erase cycles, a first average value of the first preset interval is an average a plurality of numbers of program/erase cycles in the first preset interval, and wherein the first average value of the first preset interval is less than a second average value of the second preset interval.

14. The method of claim 13, further comprising:
defining the plurality of preset intervals based on a preset number of program/erase cycles of the memory device, the plurality of preset intervals being M intervals, wherein a number of the M intervals is positively correlated with the preset number of program/erase cycles; and
determining:
that the first pass voltage or the second pass voltage is associated with an i^{th} interval based on the i^{th} interval being the first preset interval of the first number of program/erase cycles, or
that the first erase voltage or the second erase voltage is associated with the i^{th} interval based on the i^{th} interval being the second preset interval of the second number of program/erase cycles, wherein M and i are positive integers, M ≥ 2, and M ≥ i ≥ 1.

15. The method of claim 13, further comprising:
determining, in combination with a first mapping table, the first pass voltage or the first erase voltage based on the first number of program/erase cycles being in the first preset interval; and
determining, in combination with the first mapping table, the second pass voltage or the second erase voltage based on the second number of program/erase cycles being in the second preset interval,
wherein the first mapping table comprises a relationship between:
an average of the plurality of preset intervals and a corresponding one of the first pass voltage or the second pass voltage, or
an average of the plurality of preset intervals and a corresponding one of the first erase voltage or the second erase voltage.

16. The method of claim 12, further comprising:
determining the first pass voltage or the first erase voltage based on the first number of program/erase cycles; and
determining the second pass voltage or the second erase voltage based on the second number of program/erase cycles,
wherein there is a first difference between the first number of program/erase cycles and the second number of program/erase cycles, there is a second difference between the first pass voltage and the second pass voltage, there is a third difference between the first erase voltage and the second erase voltage, and wherein:
a ratio of the second difference to the first difference is constant, or
a ratio of the third difference to the first difference is constant.

17. The method of claim 16, further comprising:
defining N numbers of program/erase cycles based on a preset number of program/erase cycles of the memory device; and
determining:
that the first pass voltage or the second pass voltage is associated with j program/erase cycles based on the first number of program/erase cycles being equal to the j program/erase cycles, or
that the first erase voltage or the second erase voltage is associated with the j program/erase cycles based on the second number of program/erase cycles being equal to the j program/erase cycles, wherein N and j are positive integers, N ≥ 2, and N ≥ j ≥ 1.

18. The method of claim 16, further comprising:
determining, in combination with a second mapping table, the first pass voltage or the first erase voltage based on the first number of program/erase cycles; and
determining, in combination with the second mapping table, the second pass voltage or the second erase voltage based on the second number of program/erase cycles,
wherein the second mapping table comprises a relationship between:
each number of program/erase cycles of the memory device and a corresponding one of the first pass voltage or the second pass voltage, or
each of the number of the program/erase cycles of the memory device and a corresponding one of the first erase voltage or the second erase voltage.

19. The method of claim 12, further comprising:
applying a first erase inhibit voltage to a second word line coupled to a second memory cell during the first odd-even erase operation, the first erase inhibit voltage being less than the first pass voltage; and
applying a second erase inhibit voltage to the second word line during the second odd-even erase operation, the second erase inhibit voltage being less than the second pass voltage.

20. A memory system, comprising:
a memory array based on one or more memory devices; and
a peripheral circuit coupled to the memory array,
wherein the peripheral circuit is configured to:
during a first odd-even erase operation:
apply a first erase voltage to a source line, and
apply a first pass voltage to a first word line coupled to a first memory cell; and
during a second odd-even erase operation:
apply a second erase voltage to the source line, and
apply a second pass voltage to the first word line,
wherein a first number of program/erase cycles corresponding to the first odd-even erase operation is less than a second number of program/erase cycles corresponding to the second odd-even erase operation, and the first pass voltage is greater than the second pass voltage or the first erase voltage is greater than the second erase voltage; and
a memory controller coupled with the one or more memory devices and controlling the one or more memory devices.
